(19) United States
(12) Patent Application Publication
(10) Pub. No.: US 2019/0006623 A1
(43) Pub. Date: Jan. 3, 2019

(54) COMPOSITE LAMINATE AND METHOD FOR STORING RESIN LAYER

(71) Applicant: ZEON CORPORATION, Chiyoda-ku, Tokyo (JP)

(72) Inventor: Hiroyasu INOUE, Tokyo (JP)

(73) Assignee: ZEON CORPORATION, Chiyoda-ku, Tokyo (JP)

(21) Appl. No.: 16/064,605

(22) PCT Filed: Dec. 22, 2016
(86) PCT No.: PCT/JP2016/088581

§ 371 Date: Jun. 21, 2018

(30) Foreign Application Priority Data
Dec. 25, 2015 (JP) 2015-253065

(51) Int. Cl. H01L 51/52; B32B 27/32; B32B 27/20; B32B 15/085; B65D 81/24; H01L 51/00

(52) U.S. Cl. CPC H01L 51/5256; B32B 27/325; B32B 27/20; B32B 15/085; H01L 2251/5338; H01L 51/0097; H01L 51/5259; B32B 2264/102; B32B 2307/7242; B65D 81/24

(57) ABSTRACT

A composite layered body including: a resin layer and a first composite layer, the resin layer containing particles of which a weight change ratio when they are left to stand at 20° C. and 90% Rh for 24 hours is 3% or more, wherein the first composite layer includes a first release layer and a first gas barrier layered body in this order from a side of the resin layer side, and the first gas barrier layered body includes a first substrate layer and a first inorganic layer disposed on at least one surface of the first substrate layer.

### FIELD

The present invention relates to a composite layered body including a resin layer, and a method for storing a resin layer using the composite layered body.

### BACKGROUND

An organic electroluminescent light-emitting body (hereinafter, sometimes appropriately referred to as an “organic EL light-emitting body”) generally includes electrodes and a light-emitting layer. The light-emitting layer of the organic EL light-emitting body contains an organic material which is usually easily deteriorated with water. Therefore, in order to prevent intrusion of water into the light-emitting body, a sealing member having an excellent gas barrier property is sometimes provided to the organic EL light-emitting body (see Patent Literatures 1 and 2).

### CITATION LIST

### Patent Literature

Patent Literature 1: Japanese Patent Application Laid-Open No. 2009-190186 A

Patent Literature 2: Japanese Patent Application Laid-Open No. 2005-327687 A

### SUMMARY

### Technical Problem

Organic EL light-emitting bodies have an excellent advantage that they can be made flexible. Therefore, in order to achieve a flexible organic EL light-emitting body, the present inventor conducted research on a resin layer having an excellent gas barrier property as a flexible sealing member. However, it was difficult to attain a high gas barrier property required for organic EL light-emitting bodies with known resin layers.

The present inventor further conducted research, and found that a sufficiently high gas barrier property can be achieved by using a resin layer which includes a resin containing hygroscopic particles. When the resin layer containing hygroscopic particles is provided as a sealing member to an organic EL light-emitting body, the hygroscopic particles can adsorb moisture entering the organic EL light-emitting body. As a result, a high gas barrier property can be obtained.

However, in such a resin layer containing hygroscopic particles, the hygroscopic particles sometimes adsorb water in the air while the resin layer stored, thereby to reduce its hygroscopic function. Therefore, when the resin layer containing hygroscopic particles is stored in a usual environment, the gas barrier property is likely to decrease. It is conceivable that if the resin layer containing hygroscopic particles is stored in a highly dried environment, the high gas barrier property can be maintained. However, preparation of such a highly dried environment can lead to increased costs.

The present invention has been devised in view of the aforementioned problem. An object of the present invention is to provide: a composite layered body which includes a resin layer containing hygroscopic particles and enables storing of the resin layer while a decrease in hygroscopic function of the hygroscopic particles is suppressed; and a method for storing a resin layer, the method enabling storing of the resin layer while a decrease in hygroscopic function of the hygroscopic particles is suppressed.

### Solution to Problem

The present inventor has intensively conducted research for solving the aforementioned problem. As a result, the present inventor has found that when a composite layer including a gas barrier layered body containing a substrate layer and an inorganic layer and a release layer is disposed on the surface of a resin layer containing hygroscopic particles, moisture adsorption of the hygroscopic particles during storage can be suppressed, resulting in enabling storing of the resin layer while a decrease in hygroscopic function of the hygroscopic particles is suppressed. Thus, the present invention has been accomplished.

That is, the present invention is as follows.

(1) A composite layered body comprising: a resin layer and a first composite layer, the resin layer containing particles of which a weight change ratio when they are left to stand at 20° C. and 90% Rh for 24 hours is 3% or more, wherein

the first composite layer includes a first release layer and a first gas barrier layered body in this order from a side of the resin layer side, and

the first gas barrier layered body includes a first substrate layer and a first inorganic layer disposed on at least one surface of the first substrate layer.

(2) The composite layered body according to (1), wherein the first substrate layer contains an alicyclic polyolefin resin.

(3) The composite layered body according to (1) or (2), wherein the particles contain one or more substances selected from the group consisting of zeolite, magnesium oxide, and calcium oxide.

(4) The composite layered body according to any one of (1) to (3), wherein a moisture vapor transmission rate of the first composite layer is 5.0×10⁻² g/m²/day or less at 40° C. and 90% Rh.

(5) The composite layered body according to any one of (1) to (4), wherein the resin layer contains an adhesive resin or a thermoplastic elastomer resin.

(6) The composite layered body according to any one of (1) to (5), wherein the first inorganic layer is a layer of a material containing a metallic element.

(7) The composite layered body according to any one of (1) to (6), wherein the first inorganic layer is a layer of a material containing an aluminum element.

(8) The composite layered body according to any one of (1) to (7), comprising the first composite layer, the resin layer, and a second composite layer in this order, wherein

the second composite layer includes a second gas barrier layered body, the second gas barrier layered body including a second substrate layer and a second inorganic layer disposed on at least one surface of the second substrate layer.

(9) The composite layered body according to (8), wherein the second composite layer include a second release layer between the resin layer and the second gas barrier layered body.

(10) A method for storing a resin layer, comprising sealing and storing the composite layered body according to any one of (1) to (9) in a state of being wound up in a roll shape.

### Advantageous Effects of Invention

According to the present invention, a composite layered body which includes a resin layer containing hygroscopic particles and enables storing of the resin layer while a decrease in hygroscopic function of the hygroscopic particles is suppressed; and a method for storing a resin layer, the method allowing the resin layer to be stored while a decrease in hygroscopic function of the hygroscopic particles is suppressed, can be provided.

### BRIEF DESCRIPTION OF DRAWINGS

FIG. 1 is a cross-sectional view schematically illustrating a cross section of a composite layered body as an example according to the present invention when it is cut along a plane perpendicular to the main surface of the composite layered body.

FIG. 2 is a cross-sectional view schematically illustrating a cross section of a composite layered body as an example according to the present invention when it is cut along a plane perpendicular to the main surface of the composite layered body.

FIG. 3 is a cross-sectional view schematically illustrating a cross section of a composite layered body as an example according to the present invention when it is cut along a plane perpendicular to the main surface of the composite layered body.

FIG. 4 is a cross-sectional view schematically illustrating a cross section of a composite layered body as an example according to the present invention when it is cut along a plane perpendicular to the main surface of the composite layered body.

### DESCRIPTION OF EMBODIMENTS

Hereinafter, the present invention will be described in detail with reference to embodiments and examples. However, the present invention is not limited to the following embodiments and examples, and may be freely modified for implementation without departing from the scope of claims of the present invention and the scope of their equivalents.

In the following description, a “long-length” film refers to a film having a length that is 5 or more times the width, and preferably a film having a length that is 10 or more times the width, and specifically refers to a film having a length that allows a film to be wound up into a roll shape and stored or transported.

In the following description, unless otherwise specified, the “(meth)acrylate” is a term including both “acrylate” and “methacrylate”, the “(meth)acryl-” is a term including both “acryl-” and “methacryl-”, and the “(meth)acrylonitrile” is a term including both “acrylonitrile” and “methacrylonitrile”.

In the following description, the indication of “Rh” in the unit “% Rh” for humidity represents that the humidity is a relative humidity, unless otherwise specified.

[1. Summary of Composite Layered Body]

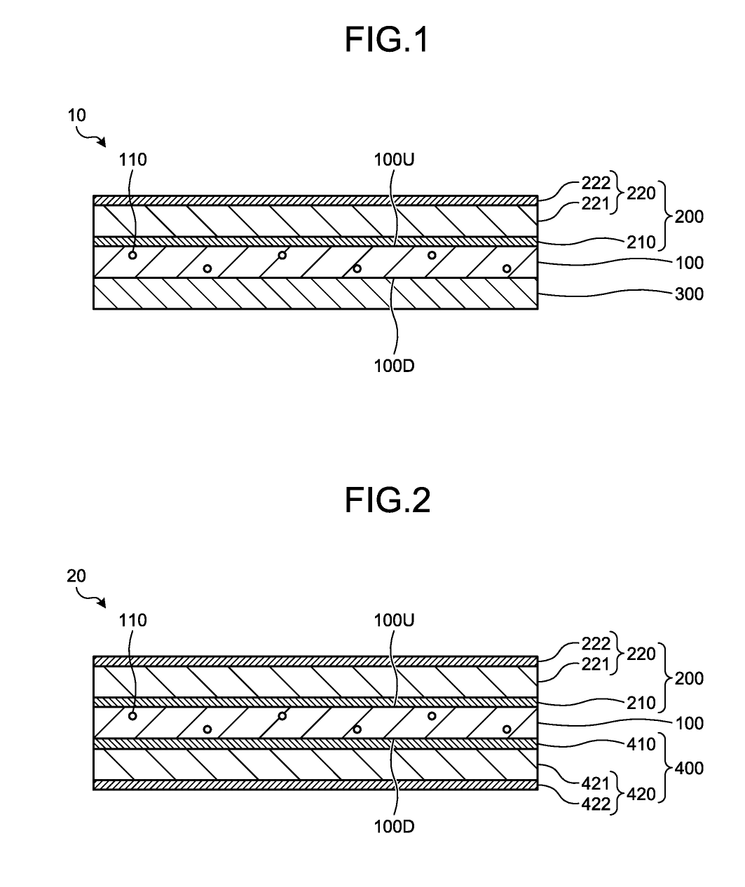

FIGS. 1 to 4 are each a cross-sectional view schematically illustrating a cross section of each of composite layered bodies 10, 20, 30, and 40 which are examples of the present invention, when it is cut along a plane perpendicular to the main surface thereof.

As indicated in examples illustrated in FIGS. 1 to 4, the composite layered bodies 10, 20, 30, and 40 each include a resin layer 100 and a first composite layer 200. The first composite layer 200 includes a first release layer 210 and a first gas barrier layered body 220 in this order from the resin layer 100 side. The first gas barrier layered body 220 includes a first substrate layer 221 and a first inorganic layer 222. The resin layer 100 contains particles 110 of which the weight change ratio when they are left to stand at 20° C. and 90% Rh for 24 hours falls within a specific range. In the following description, the particles 110 may sometimes be appropriately referred to as “hygroscopic particles”. Also, the resin layer 100 may sometimes be appropriately referred to as a “hygroscopic resin layer”. Since the hygroscopic resin layer 100 contains the hygroscopic particles 110 capable of adsorbing water, the hygroscopic resin layer 100 may function as an excellent sealing member which effectively suppresses intrusion of water when it is provided to an organic EL light-emitting body.

The first gas barrier layered body 220 may function as a gas barrier layer which blocks the moisture entering the hygroscopic resin layer 100 during the storage of the hygroscopic resin layer 100. Therefore, the first composite layer 200 including this first gas barrier layered body 220 can suppress the transmission of moisture. Thus, in the composite layered bodies 10, 20, 30, and 40, a decrease in hygroscopic function of the hygroscopic particles 110 contained in the hygroscopic resin layer 100 can be suppressed during storage.

The first composite layer 200 is usually peeled off when the hygroscopic resin layer 100 is used as a sealing member. For facilitating such peeling, the first release layer 210 of the first composite layer 200 is usually disposed to be in contact with a surface 100U of the hygroscopic resin layer 100.

Usually, a surface 100D of the hygroscopic resin layer 100 opposite to the first composite layer 200 is not exposed, and an optional layer is disposed on the surface 100D. Examples of the optional layer may include a peelable film layer 300 such as a separator film layer as illustrated in FIG. 1. It is particularly preferable that a second composite layer 400 is disposed on the surface 100D of the hygroscopic resin layer 100 as illustrated in FIGS. 2 to 4. Thus, the composite layered bodies 20, 30, and 40 preferably include the first composite layer 200, the hygroscopic resin layer 100, and the second composite layer 400 in this order.

The second composite layer 400 includes a second gas barrier layered body 420 containing a second substrate layer 421 and a second inorganic layer 422. The second gas barrier layered body 420 functions as a gas barrier layer which blocks the moisture entering the hygroscopic resin layer 100 during the storage of the hygroscopic resin layer 100. Therefore, in the composite layered bodies 20, 30, and 40, both the first composite layer 200 and the second composite layer 400 suppress the transmission of moisture. Accordingly, a decrease in hygroscopic function of the hygroscopic particles 110 contained in the hygroscopic resin layer 100 can be particularly effectively suppressed.

The second composite layer 400 is usually peeled off when the hygroscopic resin layer 100 is used as a sealing member. For facilitating such peeling, the second composite layer 400 preferably includes a second release layer 410 between the hygroscopic resin layer 100 and the second gas barrier layered body 420. This second release layer 410 is usually disposed to be in contact with the surface 100D of the hygroscopic resin layer 100.

[2. First Composite Layer]

The first composite layer includes the first gas barrier layered body and the first release layer.

<2.1. First Gas Barrier Layered Body>

The first gas barrier layered body includes a first substrate layer and a first inorganic layer disposed on at least one surface of the first substrate layer. The first inorganic layer may be disposed on only one surface of the first substrate layer, or may be disposed on both surfaces of the first substrate layer. Usually, the first inorganic layer is disposed in direct contact with the surface of the first substrate layer, and therefore the first inorganic layer and the first substrate layer are in contact with each other. However, when the surface of the first substrate layer has many convex portions which may cause cracking of the first inorganic layer, an organic layer such as an overcoat layer may be formed between the first inorganic layer and the first substrate layer. Accordingly, the first inorganic layer may be disposed indirectly on the surface of the first substrate layer via an optional layer.

(2.1.1. First Substrate Layer)

The first substrate layer is a layer capable of supporting the first inorganic layer and maintaining the strength of the first gas barrier layered body. Although the first substrate layer may be a film layer having a multilayer structure that contains two or more layers, the first substrate layer is usually a film layer having a monolayer structure that contains only one layer. Such a first substrate layer is usually a resin film layer containing a resin.

The resin contained in the first substrate layer is preferably a resin that prevents moisture from passing therethrough. Examples of the resin that prevents moisture from passing therethrough may include a polypropylene resin, a polyimide resin, a polyethylene terephthalate resin, and an alicyclic polyolefin resin. Among these, an alicyclic polyolefin resin is particularly preferable.

An alicyclic polyolefin resin refers to a resin that contains an alicyclic olefin polymer, and, as necessary, another optional component.

The alicyclic polyolefin resin has a low moisture vapor transmission rate. Therefore, the first substrate layer containing the alicyclic polyolefin resin has a high gas barrier property. Consequently, the gas barrier property of the first gas barrier layered body can thereby be enhanced.

The alicyclic polyolefin resin generates little outgas. Thus, by adopting a film layer of the alicyclic polyolefin resin as the first substrate layer, the emission amount of the outgas from the film layer into the reduced pressure system can be reduced in a process including the reduction in pressure within the system for forming the first inorganic layer (for example, vapor deposition, sputtering, etc.). Thus, since the favorable first inorganic layer can be formed, the gas barrier property of the first gas barrier layered body can be enhanced.

Furthermore, since the alicyclic polyolefin resin has low hygroscopicity, the amount of moisture contained in the alicyclic polyolefin resin is small. Accordingly, the water vapor as outgas can be particularly reduced. Thus, it is possible to prevent the hygroscopic particles contained in the hygroscopic resin from absorbing water vapor emitted from the first substrate layer, and thereby a decrease in hygroscopic function of the hygroscopic particles can be effectively suppressed. Furthermore, since the decrease in hygroscopic function of the hygroscopic particles can be effectively suppressed, the amount of the hygroscopic particles to be used to achieve the desired gas barrier property can be reduced. As a result, the haze of the hygroscopic resin layer can be decreased.

The film layer produced by melt-extruding the alicyclic polyolefin resin usually has a favorable surface smoothness and small projections on the surface, which may cause cracking of an inorganic layer. Accordingly, the alicyclic polyolefin resin film layer can achieve reduction of the moisture vapor transmission rate with a thinner inorganic layer on the surface thereof than in a case with a film layer having a low surface accuracy. Thus, when the film layer of the alicyclic polyolefin resin is adopted as the first substrate layer, productivity and flexibility of the composite layered body can be enhanced.

The alicyclic olefin polymer is a thermoplastic polymer having an alicyclic structure. The alicyclic olefin polymer may have the alicyclic structure in its main chain or side chain. Further, the alicyclic olefin polymer may have the alicyclic structure in both the main chain and the side chain.

Examples of the alicyclic structure may include a saturated alicyclic hydrocarbon (cycloalkane) structure, and an unsaturated alicyclic hydrocarbon (cycloalkene and cycloalkyne) structure. Among these, from the viewpoint of mechanical strength and heat resistance, a cycloalkane structure and a cycloalkene structure are preferable, and a cycloalkane structure is particularly preferable.

The number of carbon atoms constituting the alicyclic structure per one alicyclic structure is preferably 4 or more, and more preferably 5 or more, and is preferably 30 or less, more preferably 20 or less, and particularly preferably 15 or less. When the number of carbon atoms constituting the alicyclic structure falls within this range, mechanical strength, heat resistance, and moldability of the resin are highly balanced.

In the alicyclic olefin polymer, the ratio of the structural unit having the alicyclic structure is preferably 55% by weight or more, more preferably 70% by weight or more, and particularly preferably 90% by weight or more. When the ratio of the structural unit having the alicyclic structure in the alicyclic olefin polymer falls within this range, transparency and heat resistance of the resin become favorable.

Examples of the alicyclic olefin polymer may include a norbornene polymer, a monocyclic cyclic-olefin polymer, a cyclic conjugated diene polymer, a vinyl alicyclic hydrocarbon polymer, and hydrogenated products of these. Among these, from the viewpoint of transparency and moldability, a norbornene polymer is particularly preferable.

Examples of the norbornene polymer may include a ring-opening polymer of a monomer having a norbornene structure and a hydrogenated product thereof; and an addition polymer of a monomer having a norbornene structure and a hydrogenated product thereof. Examples of the ring-opening polymer of the monomer having a norbornene structure may include a ring-opening homopolymer of one type of monomers having a norbornene structure, a ring-opening copolymer of two or more types of monomers having a norbornene structure, and a ring-opening copolymer of a monomer having a norbornene structure with an optional monomer copolymerizable therewith. Examples of the addition polymer of the monomer having a norbornene structure may include an addition homopolymer of one type of monomers having a norbornene structure, an addition copolymer of two or more types of monomers having a norbornene structure, and an addition copolymer of a monomer having a norbornene structure with an optional monomer copolymerizable therewith. Among these, from the viewpoint of moldability, heat resistance, low hygroscopicity, size stability, and light-weight property, a hydrogenated product of a ring-opening polymer of a monomer having a norbornene structure is particularly preferable.

Examples of the monomer having a norbornene structure may include bicyclo[2.2.1]hept-2-ene (common name: norbornene), tricyclo[4.3.0.1^{2,5}]dec-3,7-diene (common name: dicyclopentadiene), 7,8-benzotricyclo[4.3.0.1^{2,5}]dec-3-ene (common name: methanotetrahydrofluorene), tetracyclo[4.4.0.1^{2,5}.1^{7,10}]dodeca-3-ene (common name: tetracyclododecene), and derivatives of these compounds (for example, those with a substituent on the ring). Examples of the substituent herein may include an alkyl group, an alkylene group, and a polar group. A plurality of substituents, which may be the same as or different from each other, may be bonded to the ring. As the monomer having a norbornene structure, one type thereof may be solely used, and two or more types thereof may also be used in combination at any ratio.

Examples of the type of the polar group may include a heteroatom, and an atomic group having a heteroatom. Examples of the heteroatom may include an oxygen atom, a nitrogen atom, a sulfur atom, a silicon atom, and a halogen atom. Specific examples of the polar group may include a carboxyl group, a carbonyloxycarbonyl group, an epoxy group, a hydroxyl group, an oxy group, an ester group, a silanol group, a silyl group, an amino group, a nitrile group, and a sulfonic acid group.

Examples of a monomer that is ring-opening copolymerizable with the monomer having a norbornene structure may include monocyclic olefins such as cyclohexene, cycloheptene, and cyclooctene, and derivatives thereof; and cyclic conjugated dienes such as cyclohexadiene and cycloheptadiene, and derivatives thereof. As the monomer that is ring-opening copolymerizable with the monomer having a norbornene structure, one type thereof may be solely used, and two or more types thereof may also be used in combination at any ratio.

The ring-opening polymer of the monomer having a norbornene structure may be produced, for example, by polymerization or copolymerization of the monomer in the presence of a ring-opening polymerization catalyst.

Examples of a monomer that is addition copolymerizable with the monomer having a norbornene structure may include α-olefins of 2 to 20 carbon atoms such as ethylene, propylene, and 1-butene, and derivatives thereof; cycloolefins such as cyclobutene, cyclopentene, and cyclohexene, and derivatives thereof; and non-conjugated dienes such as 1,4-hexadiene, 4-methyl-1,4-hexadiene, and 5-methyl-1,4-hexadiene. Among these, α-olefin is preferable, and ethylene is more preferable. As the monomer that is addition copolymerizable with the monomer having a norbornene structure, one type thereof may be solely used, and two or more types thereof may also be used in combination at any ratio.

The addition polymer of the monomer having a norbornene structure may be produced, for example, by polymerization or copolymerization of the monomer in the presence of an addition polymerization catalyst.

The hydrogenated products of the ring-opening polymer and the addition polymer described above may be produced, for example, by hydrogenating an unsaturated carbon-carbon bond, preferably 90% or more of the unsaturated carbon-carbon bond, in a solution of the ring-opening polymer and the addition polymer in the presence of a hydrogenation catalyst containing a transition metal such as nickel and palladium.

As the alicyclic olefin polymer, one type of these polymers may be solely used, and two or more types thereof may also be used in combination at any ratio. The first substrate layer may have a structure in which a plurality of types of alicyclic polyolefin resins form corresponding layers.

The weight-average molecular weight (Mw) of the alicyclic olefin polymer is preferably 10,000 or more, more preferably 15,000 or more, and particularly preferably 20,000 or more, and is preferably 100,000 or less, more preferably 80,000 or less, and particularly preferably 50,000 or less. When the weight-average molecular weight falls within such a range, mechanical strength and moldability of the first substrate layer are highly balanced.

The molecular weight distribution (Mw/Mn) of the alicyclic olefin polymer is preferably 1.2 or more, more preferably 1.5 or more, and particularly preferably 1.8 or more, and is preferably 3.5 or less, more preferably 3.0 or less, and particularly preferably 2.7 or less. Mn herein represents a number-average molecular weight. When the molecular weight distribution is equal to or more than the lower limit value of the above-described range, productivity of the polymer can be enhanced while production costs can be suppressed. When the molecular weight distribution is equal to or less than the upper limit value, the amount of the low-molecular components is reduced. Thus, relaxation during high-temperature exposure can be suppressed and the stability of the first substrate layer can be enhanced.

The weight-average molecular weight (Mw) and the number-average molecular weight (Mn) mentioned above may be measured as a polyisoprene-equivalent value by gel permeation chromatography using cyclohexane as a solvent. When the sample is not dissolved in cyclohexane, toluene may be used as the solvent. When toluene is used as the solvent, the weight-average molecular weight (Mw) and the number-average molecular weight (Mn) may be measured as a polystyrene-equivalent value.

The amount of the alicyclic olefin polymer in the alicyclic polyolefin resin is preferably 50% by weight or more, and more preferably 70% by weight or more. When the amount of the alicyclic olefin polymer falls within such a range, the alicyclic polyolefin resin may have desired properties.

Examples of optional components that may be contained in the alicyclic polyolefin resin may include an antioxidant, a heat stabilizer, a light stabilizer, an ultraviolet absorber, an antistatic agent, a dispersant, a chlorine scavenger, a flame retardant, a crystallization nucleating agent, a reinforcing agent, an anti-blocking agent, an anti-fogging agent, a releasing agent, a pigment, an organic or inorganic filler, a neutralizing agent, a lubricant, a decomposing agent, a metal inactivating agent, an antifouling agent, an antimicrobial agent, a polymer other than the alicyclic olefin polymer, and a thermoplastic elastomer. One type of these may be solely used, and two or more types thereof may also be used in combination at any ratio.

It is preferable that the resin contained in the first substrate layer has high transparency. Specifically, when the resin contained in the first substrate layer is formed into a test piece having a thickness of 1 mm, the total light transmittance of the test piece of the resin is preferably 70% or more, more preferably 80% or more, and particularly preferably 90% or more.

The thickness of the first substrate layer is preferably 10 μm or more, and more preferably 30 μm or more, and is preferably 300 μm or less, more preferably 250 μm or less, and further more preferably 100 μm or less. The thickness of the first substrate layer may be measured by a contact-type film thickness meter. Specifically, thicknesses of the layer are measured at equal intervals on a certain straight line at 10 points and an average thereof is calculated, and the average may be adopted as the measured value of the thickness.

The thermal expansion rate of the first substrate layer is preferably 70 ppm/K or less, more preferably 50 ppm/K or less, and further preferably 40 ppm/K or less. The thermal expansion rate may be determined by preparing the first substrate layer as a test piece of 20 mm×5 mm, and measuring the elongation of the length of the test piece when it is warmed from 30° C. to 130° C. under conditions of a load of 5.0 g, a nitrogen flow rate of 100 cc/min, and a heating rate of 0.5° C./min.

The humidity expansion rate of the first substrate layer is preferably 30 ppm/% Rh or less, more preferably 10 ppm/% Rh or less, and further preferably 1.0 ppm/% Rh or less. The humidity expansion rate may be determined by preparing the first substrate layer as a test piece of 20 mm×5 mm, and measuring the elongation of the length of the test piece when the humidity is increased from 30% Rh to 80% Rh under conditions of a load of 5.0 g, a nitrogen flow rate of 100 cc/min, a temperature of 25° C., and a humidifying rate of 5.0%/min.

The glass transition temperature of the resin contained in the first substrate layer is preferably 110° C. or higher, more preferably 130° C. or higher, and particularly preferably 160° C. or higher. When the resin contained in the first substrate layer has such a high glass transition temperature, thermal shrinkage of the first substrate layer between before and after the thermal history such as in a high-temperature environment can be suppressed.

When the preferable thermal expansion rate, humidity expansion rate, and glass transition temperature as above are imparted to the first substrate layer, the composite layered body with suppressed decrease in gas barrier property in a high-temperature and high-humidity environment can be obtained.

In order to suppress blocking, the surface of the first substrate layer opposite to the first inorganic layer may have a concavo-convex structure.

The method for producing the first substrate layer is not particularly limited, and may adopt any of a melt molding method and a solution casting method. More particularly, the melt molding method may be categorized into an extrusion molding method, a press molding method, an inflation molding method, an injection molding method, a blow molding method, a stretch molding method, and the like. Among these methods, in order to obtain the first substrate layer having excellent mechanical strength and surface accuracy, an extrusion molding method, an inflation molding method, and a press molding method are preferable. Among these, from the viewpoint of enabling efficient and easy production of the first substrate layer, an extrusion molding method is particularly preferable.

The method for producing the first substrate layer may include a stretching step of stretching a film. By the production method including the stretching step, a stretched film may be obtained as the first substrate layer. When a stretched film is used as the first substrate layer, it is possible to suppress the thermal expansion rate of the first substrate layer and further reduce the deterioration of the gas barrier property in a high-temperature and high-humidity environment.

(2.1.2. First Inorganic Layer)

The first inorganic layer is a layer formed of an inorganic material. This first inorganic layer can suppress the transmission of components such as moisture and oxygen from one surface of the front and rear surfaces of the first gas barrier layered body to the other surface. Thus, the first inorganic layer can block the moisture entering the hygroscopic resin layer.

Preferable examples of the inorganic material that may be contained in the first inorganic layer may include metals; oxides, nitrides, and nitride oxides of metals; oxides, nitrides, and nitride oxides of silicon; DLC (diamond-like carbon); and materials obtained by mixing two or more of these materials. Among these, from the viewpoint of achieving a high gas barrier property, materials containing a metallic element (single element metal, metal oxide, metal nitride, metal nitride oxide, and the like) are preferable, and a material containing an aluminum element is preferable. From the viewpoint of affinity to the alicyclic polyolefin resin that is a material of the first substrate layer, DLC is particularly preferable.

Examples of silicon oxides may include SiOx. From the viewpoint of simultaneously achieving both the transparency and water vapor barrier property of the first inorganic layer, x herein preferably satisfies 1.4<x<2.0. SiOC may also be exemplified as the silicon oxide.

Examples of silicon nitrides may include SiNy. From the viewpoint of simultaneously achieving both the transparency and water vapor barrier property of the first inorganic layer, y herein preferably satisfy 0.5<y<1.5.

Examples of silicon nitride oxides may include SiOpNq. If importance is given to the improvement in the adhesion of the first inorganic layer, it is preferable to select p and q so as to satisfy 1<p<2.0 and 0.0<q<1.0 whereby the first inorganic layer is made as an oxygen-rich film. If importance is given to the improvement in the water vapor barrier property of the first inorganic layer, it is preferable to select p and q so as to satisfy 0<p<0.8 and 0.8<q<1.3 whereby the first inorganic layer is made as a nitrogen-rich film.

Examples of the oxide, nitride, and nitride oxide of aluminum may include AlOx, AlNy, and AlOpNq.

The thickness of the first inorganic layer is preferably 50 nm or more, more preferably 80 nm or more, and particularly preferably 100 nm or more, and is preferably 2,500 nm or less, more preferably 2,000 nm or less, and particularly preferably 1,500 nm or less. When the thickness of the first inorganic layer is equal to or more than the lower limit value of the aforementioned range, favorable gas barrier property can be attained. When the thickness is equal to or less than the upper limit value of the aforementioned range, the composite layered body can be made thin.

The first inorganic layer may be formed by a film formation method, such as, a vapor deposition method, a sputtering method, an ion plating method, an ion-beam assisted vapor deposition method, an arc discharge plasma vapor deposition method, a thermal CVD method, or a plasma CVD method, for example, on the surface of the first substrate layer serving as a support. Among these, a chemical vapor deposition method, such as a thermal CVD method or a plasma CVD method, is preferably employed. According to the chemical vapor deposition method, by adjusting a gas component(s) used in film formation, the first inorganic layer having flexibility can be formed. When the first inorganic layer is flexible, the first inorganic layer can follow deformation of the first substrate layer and size change of the first substrate layer in a high-temperature and high-humidity environment. According to the chemical vapor deposition method, film can be formed at a high film formation rate in an environment with a low degree of vacuum, and a favorable gas barrier property can be achieved. When the first inorganic layer is formed by the chemical vapor deposition method as described above, the thickness of the first inorganic layer is preferably 300 nm or more, and more preferably 500 nm or more, and is preferably 2,000 nm or less, and more preferably 1,500 nm or less.

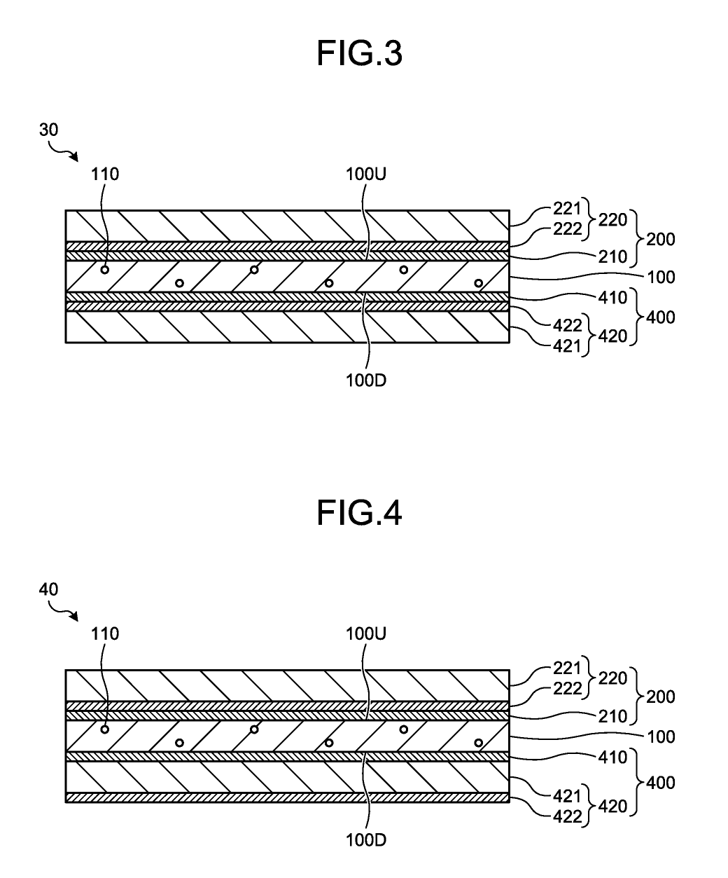

In the first gas barrier layered body, although the first inorganic layer may be disposed on both the surfaces of the first substrate layer, the first inorganic layer is usually be disposed on one of the surfaces. In this case, the first inorganic layer may be disposed on the surface of the first substrate layer on the hygroscopic resin layer side (see FIG. 3 and FIG. 4), or may be disposed on the surface of the first substrate layer opposite to the hygroscopic resin layer (see FIG. 1 and FIG. 2).

When the first inorganic layer is disposed on the surface of the first substrate layer opposite to the hygroscopic resin layer, working process of the first substrate layer in a state where the first inorganic layer has been formed is shortened. Thus, damage due to deformation or impact externally applied to the first inorganic layer can be reduced. As a result, the possibility of impairing the gas barrier property of the first inorganic layer can be decreased, and this is advantageous. When the first inorganic layer is formed after the completion of layering from the hygroscopic resin layer to the first substrate layer, vacuum drying of the first substrate layer and the hygroscopic resin layer can be performed by the vacuum process during formation of the first inorganic layer.

On the other hand, when the first inorganic layer is disposed on the surface of the first substrate layer on the hygroscopic resin layer side, the first inorganic layer is positioned inside the first substrate layer. Thus, damage of the first inorganic layer due to external force can be prevented. Thus, cracks are unlikely to be generated in the first inorganic layer, thereby preventing impairment of the gas barrier property. Furthermore, since the first inorganic layer usually has high adhesiveness to both the first substrate layer and the first release layer, when the first inorganic layer is disposed on the surface of the first substrate layer on the hygroscopic resin layer side, it is possible to increase the adhesiveness between the first gas barrier layered body and the first release layer.

Only one first inorganic layer may be disposed to one surface of the first substrate layer, or two or more first inorganic layers may be disposed thereto. From the viewpoint of production costs and secured flexibility, it is preferable to dispose only one layer thereof, nevertheless two or more layers of the first inorganic layer may be disposed to achieve still better gas barrier property. When two or more first inorganic layers are layered, the total thickness thereof preferably falls within the aforementioned preferred range of the thickness.

(2.1.3. Optional Layer)

The first gas barrier layered body may further include an optional layer in combination with the first substrate layer and the first inorganic layer. For example, when two or more first inorganic layers are disposed on one surface of the first substrate layer, the first gas barrier layered body may include an organic layer between the two or more first inorganic layers.

[2.2. First Release Layer]

The first release layer is a layer having a release property. The release property herein refers to a property that facilitates peeling. Thus, the first composite layer including the first release layer can be easily peeled off the hygroscopic resin layer when compared with a case where the first release layer is not provided thereto.

The first release layer may be formed of a material having a release property. As the material having a release property, those obtained by curing a release agent containing a curable silicone resin are preferable. The release agent herein may be of a type that contains as a main ingredient a curable silicone resin, or of a modified silicone type which is capable of being modified by a polymerization reaction such as graft polymerization with an organic resin such as a urethane resin, an epoxy resin, and an alkyd resin.

As the curable silicone resin, any curing-reaction type silicone resin, such as those of an addition type, a condensation type, an ultraviolet curable type, an electron beam curable type, or a solvent-free type may be used. Specific examples of the curable silicone resins may include KS-774, KS-775, KS-778, KS-779H, KS-847, KS-847T, KS-856, X-62-2422, and X-62-2461 manufactured by Shin-Etsu Chemical Co., Ltd.; DKQ3-202, DKQ3-203, DKQ3-204, DKQ3-205, and DKQ3-210 manufactured by Dow Corning Asia; YSR-3022, TPR-6700, TPR-6720, and TPR-6721 manufactured by Toshiba Silicone Co., Ltd.; and SD7220, SD7226, and SD7229 manufactured by Toray Dow Corning Co., Ltd. One type of these release agents may be solely used, and two or more types thereof may also be used in combination at any ratio.

In order to adjust the release property of the first release layer, a release controlling agent may be used in combination with the release agent. A catalyst is usually used in combination with the release agent.

The first release layer may be formed by, for example, applying a release agent onto a surface to which the release property is to be imparted, and curing the same. Thus, for example, the first release layer may be formed by first obtaining the first gas barrier layered body, and then applying a release agent onto the surface of the first gas barrier layered body and curing the same. Further, for example, the first release layer may be formed by, before the first gas barrier layered body is obtained, applying a release agent onto a surface of a layer constituting the first gas barrier layered body, such as the first substrate layer and the first inorganic layer, and curing the release agent. Examples of the method for applying the release agent may include a roll coating method, a die coating method, a gravure coating method, a bar coating method, and a doctor blade coating method.

The thickness of the release agent is not particularly limited, and is preferably 0.1 μm to 2.0 μm.

[2.3. Moisture Vapor Transmission Rate of First Composite Layer]

The moisture vapor transmission rate of the first composite layer in an environment at a temperature of 40° C. and a humidity of 90% Rh is preferably 5.0×10⁻² g/m²/day or less, more preferably 5.0×10⁻³ g/m²/day or less, and particularly preferably 5.0×10⁻⁴ g/m²/day or less. The aforementioned unit “g/m²/day” herein represents a weight of water vapor per unit area that passes the first composite layer per one day. When the first composite layer has the excellent gas barrier property represented by the aforementioned moisture vapor transmission rate, a decrease in hygroscopic function of the hygroscopic particles contained in the hygroscopic resin layer can be effectively suppressed. The lower limit of the moisture vapor transmission rate is desirably 0 g/m²/day. However, even when the moisture vapor transmission rate thereof is equal to or more than this value, the first composite layer may be suitably used as long as the moisture vapor transmission rate thereof is equal to or less than the aforementioned upper limit.

The moisture vapor transmission rate of a film may be measured by the following method.

A film to be measured is punched to obtain a sample having an appropriate size. Using a differential pressure measuring device having a circular measurement region with a diameter of 8 cm, pressure by water vapor equivalent to that at 40° C. and 90% Rh is created on both sides of the sample to measure the moisture vapor transmission rate.

[3. Hygroscopic Resin Layer]

The hygroscopic resin layer is a resin layer containing hygroscopic particles, and is usually disposed to be in contact with the first composite layer. Since the hygroscopic particles have hygroscopicity, they can adsorb moisture. Therefore, when this hygroscopic resin layer is disposed to an organic EL light-emitting body, the organic EL light-emitting body can be appropriately sealed, and deterioration due to water of an organic component in the organic EL light-emitting body can be effectively suppressed.

[3.1. Hygroscopic Particles]

The hygroscopic particles are particles of which the weight change ratio when they are left to stand at 20° C. and 90% Rh for 24 hours falls within a specific range. Specifically, the weight change ratio is usually 3% or more, preferably 10% or more, and more preferably 15% or more. The upper limit of the weight change ratio is not particularly limited, and is preferably 100% or less. When the hygroscopic particles having such high hygroscopicity are used, the hygroscopic resin layer having a high gas barrier property can be achieved.

The weight change ratio may be calculated according to the following equation (A1). In the following equation (A1), W1 represents the weight of particles before they are left to stand in an environment of 20° C. and 90% Rh, and W2 represents the weight of particles after they are left to stand in an environment of 20° C. and 90% Rh for 24 hours.

Weight change ratio=(W2−W1)/W1×100 (A1)

Examples of a material contained in the hygroscopic particles may include: an inorganic metal oxide such as barium oxide, magnesium oxide, calcium oxide, and strontium oxide; an organometallic compound disclosed in Japanese Patent Application Laid-Open No. 2005-298598 A; and a substance capable of physically adsorbing moisture, such as zeolite, silica gel, and active alumina. Among these, one or more substances selected from the group consisting of zeolite, magnesium oxide, and calcium oxide are preferably contained as a material of the hygroscopic particles. Zeolite, magnesium oxide, and calcium oxide have especially high hygroscopic performance. For example, their weight change ratios as high as 10% to 30% when they are left to stand at 20° C. and 90% Rh for 24 hours can be easily achieved. Zeolite releases water when dried, and therefore can be recycled. Magnesium oxide is transformed into magnesium hydroxide when adsorbing moisture and has relatively mild hygroscopicity. However, magnesium oxide has favorable dispersibility. Calcium oxide is excellent in both hygroscopicity and dispersibility. As the material of the hygroscopic particles such as those described above, one type thereof may be solely used, and two or more types thereof may also be used in combination at any ratio.

The average dispersed particle diameter of the hygroscopic particles is preferably 3 nm or more, more preferably 5 nm or more, and particularly preferably 10 nm or more, and is preferably 10 μm or less, more preferably 150 nm or less, and particularly preferably 30 nm or less. When the average dispersed particle diameter of the hygroscopic particles is equal to or more than the lower limit value of the aforementioned range, the hygroscopic particles can have enhanced dispersibility in the hygroscopic resin layer. When the average dispersed particle diameter thereof is equal to or less than the upper limit value of the aforementioned range, the hygroscopic resin layer can have uniform thickness. Furthermore, when the average dispersed particle diameter of the hygroscopic particles is 30 nm or less, the haze value can be decreased to enhance the transparency of the hygroscopic resin layer.

Unless otherwise stated, the average dispersed particle diameter of particles represents the volume average particle diameter. When a plurality of particles agglomerate to form agglomerated particles, the average dispersed particle diameter represents the volume average particle diameter of the agglomerated particles. The volume average particle diameter of particles may be measured after the particles are prepared in a slurry state. As a measuring device for particles having a nano-order particle diameter, a dynamic light scattering Nanotrac particle size analyzer (“UPA-EX” manufactured by Nikkiso Co., Ltd.) may be used. As a measuring device for particles having particle diameter of about 0.1 μm to 500 μm, a Microtrac particle size distribution measuring device (“9320-HRA” manufactured by Nikkiso Co., Ltd.) may be used.

The amount of the hygroscopic particles in the hygroscopic resin layer is preferably 0.1 g/m² or more, more preferably 0.5 g/m² or more, and particularly preferably 1 g/m² or more, and is preferably 40 g/m² or less, more preferably 25 g/m² or less, and particularly preferably 15 g/m² or less. The aforementioned unit “g/m²” herein represents the weight of the hygroscopic particles per unit area of the hygroscopic resin layer. When the amount of the hygroscopic particles is equal to or more than the lower limit value of the aforementioned range, the gas barrier property of the hygroscopic resin layer can be effectively enhanced. When the amount thereof is equal to or less than the upper limit value of the aforementioned range, the hygroscopic resin layer can have enhanced transparency, flexibility, and workability.

The ratio of the hygroscopic particles in the hygroscopic resin layer is preferably 0.5% by weight or more, more preferably 2% by weight or more, and particularly preferably 4% by weight or more, and is preferably 50% by weight or less, more preferably 40% by weight or less, and particularly preferably 35% by weight or less. When the ratio of the hygroscopic particles is equal to or more than the lower limit value of the aforementioned range, gas barrier property of the hygroscopic resin layer can be effectively enhanced. When the ratio thereof is equal to or less than the upper limit value of the aforementioned range, the hygroscopic resin layer can have enhanced transparency, adhesiveness, flexibility, and workability. When the ratio thereof is equal to or less than the upper limit value of the aforementioned range, a change in refractive index and adhesiveness of the hygroscopic particles when adsorbing moisture can be suppressed.

<3.2. Components Other than Hygroscopic Particles to be Contained in Hygroscopic Resin Layer>

The hygroscopic resin layer is a resin layer containing hygroscopic particles and a polymer. Although the resin to be contained in the hygroscopic resin layer may be a resin of a wide range which contains hygroscopic particles and a polymer, an adhesive resin and a thermoplastic elastomer resin are preferable. The adhesive resin and thermoplastic elastomer resin can easily achieve dispersion of the hygroscopic particles. Since the hygroscopic resin layer formed of the adhesive resin or the thermoplastic elastomer resin eliminates the need for a treatment such as UV irradiation which can damage the light-emitting body when an organic EL light-emitting body is sealed by using the hygroscopic resin layer. Therefore, the sealing operation can be easily performed.

(3.2.1. Adhesive Resin)

The adhesive resin is a resin containing an adhesive polymer. The adhesive polymer is a polymer that may exhibit adhesiveness of the adhesive resin. As such an adhesive polymer, one type thereof may be solely used, and two or more types thereof may also be used in combination at any ratio.

Examples of the adhesive polymer may include polymers having a carboxyl group and/or a hydroxyl group as a functional group. Among these, a polymer having a hydroxyl group as a main functional group is preferable.

The polymer having a hydroxyl group as a main functional group herein refers to a polymer containing a carboxyl group and/or a hydroxyl group with a ratio of the hydroxyl group being usually 50% or more, preferably 60% or more relative to the total of the carboxyl group and the hydroxyl group. The ratio of the hydroxyl group in the polymer may be measured by a titration analysis.

Examples of the adhesive polymer may include acrylic polymers contained in adhesive agents, such as an acrylic adhesive agent, a urethane-based adhesive agent, and a polyacrylamide-based adhesive agent.

The glass transition temperature of the adhesive polymer is usually 40° C. or lower, and preferably 0° C. or lower. The lower limit of the glass transition temperature is usually −80° C. or higher, and preferably −60° C. or higher. When the glass transition temperature of the adhesive polymer falls within this range, there are obtained advantages in which, even in a system containing particles, adhesive remaining on an adherend can be suppressed and the polymer has appropriate adhesiveness. The “adhesive remaining” herein means a phenomenon in which, when an adhesive resin layer is attached to a certain adherend and then peeled off from the adherend, the adhesive resin remains on the adherend.

An acrylic polymer refers to a polymer containing a structural unit derived from an acrylic monomer. Examples thereof may include a polymer obtained by polymerizing an acrylic monomer; and a polymer obtained by copolymerizing an acrylic monomer and a monomer copolymerizable with the acrylic monomer.

Examples of the acrylic monomer may include alkyl (meth)acrylates. The average carbon number of the alkyl group of the alkyl (meth)acrylate is preferably 1 to 12, and more preferably 3 to 8. Specific examples of the alkyl (meth)acrylate may include methyl (meth)acrylate, ethyl (meth)acrylate, butyl (meth)acrylate, 2-ethylhexyl (meth)acrylate, and isooctyl (meth)acrylate. As the alkyl (meth)acrylate, one type thereof may be solely used, and two or more types thereof may also be used in combination at any ratio.

Preferable examples of the monomer copolymerizable with the acrylic monomer may include a monomer having a functional group, a nitrogen atom-containing monomer, and a modifying monomer.

Examples of the monomer having a functional group may include a monomer having a carboxyl group, a monomer having a hydroxyl group, and a monomer having an epoxy group. Examples of the monomer having a carboxyl group may include acrylic acid, methacrylic acid, fumaric acid, maleic acid, and itaconic acid. Examples of the monomer having a hydroxyl group may include 2-hydroxyethyl (meth)acrylate, hydroxybutyl (meth)acrylate, hydroxyhexyl (meth)acrylate, and N-methylol(meth)acrylamide. Examples of the monomer having an epoxy group may include glycidyl (meth)acrylate. When the acrylic monomer and the monomer having a functional group are used in combination, it is preferable that the acrylic monomer is contained in an amount of 90% by weight to 99.8% by weight and the monomer having a functional group is contained in an amount of 10% by weight to 0.2% by weight, relative to 100% by weight of the total amount of the acrylic monomer and the monomer having a functional group.

Examples of the nitrogen atom-containing monomer may include (meth)acrylamide, N,N-dimethyl(meth)acrylamide, N,N-diethyl(meth)acrylamide, (meth)acryloylmorpholine, (meth)acrylonitrile, vinylpyrrolidone, N-cyclohexylmaleimide, itaconimide, and N,N-dimethylaminoethyl(meth)acrylamide. When the acrylic monomer and the nitrogen atom-containing monomer are used in combination, it is preferable that the acrylic monomer is contained in an amount of 90% by weight to 99.8% by weight and the nitrogen atom-containing monomer is contained in an amount of 10% by weight to 0.2% by weight, relative to 100% by weight of the total amount of the acrylic monomer and the nitrogen atom-containing monomer.

Examples of the modifying monomer may include vinyl acetate and styrene. When the acrylic monomer and the modifying monomer are used in combination, it is preferable that the acrylic monomer is contained in an amount of 90% by weight to 99.8% by weight and the modifying monomer is contained in an amount of 10% by weight to 0.2% by weight, relative to 100% by weight of the total amount of the acrylic monomer and the modifying monomer.

As the monomer copolymerizable with the acrylic monomer, one type thereof may be solely used, and two or more types thereof may also be used in combination at any ratio. As a particularly preferable adhesive polymer, an adhesive polymer containing butyl acrylate and methyl acrylate as main polymer components is exemplified.

As the adhesive polymer, those contained in commercially available adhesive agents may be used. Although some commercially available adhesive agents may contain a solvent, an additive, and the like, the adhesive agent containing these as it is may be available for producing the adhesive resin. Examples of the commercially available adhesive agent containing an acrylic polymer may include trade name “X-311033S” (manufactured by Saiden Chemical Industry Co., Ltd., solvent: ethyl acetate, solid content: 35%), and trade name “OC3496” (manufactured by Saiden Chemical Industry Co., Ltd.).

The adhesive resin may contain inorganic particles other than the hygroscopic particles as an optional component. As the inorganic particles, particles containing a metal oxide are preferable. Among these, particles containing a metal oxide and an organic substance that has a reactive functional group and modifies the surface of the metal oxide are preferable. More specifically, a coated particle containing a particle of a metal oxide and an organic substance that has a reactive functional group and modifies the surface of the particle (hereinafter, which may be appropriately referred to as a “reactive modified metal oxide particle”) is preferable. The reactive functional group may be in a state where it has an interaction, such as hydrogen bonding. Alternatively, the reactive functional group may not be in such a state and may be in a state of being capable of interacting with another substance.

Examples of the metal oxide may include titanium oxide, zinc oxide, zirconium oxide, antimony oxide, tin-doped indium oxide (ITO), antimony-doped tin oxide (ATO), fluorine-doped tin oxide (FTO), phosphorus-doped tin oxide (PTO), zinc antimonate (AZO), indium-doped zinc oxide (IZO), aluminum-doped zinc oxide, gallium-doped zinc oxide, cerium oxide, aluminum oxide, and tin oxide. As the metal oxide, one type thereof may be solely used, and two or more types thereof may also be used in combination at any ratio.

Examples of the reactive functional group in the organic substance having the reactive functional group may include a hydroxyl group, a phosphoric acid group, a carboxyl group, an amino group, an alkoxy group, an isocyanate group, an acid halide, an acid anhydride, a glycidyl group, a chlorosilane group, and an alkoxysilane group. One type of these may be solely used, and two or more types thereof may also be used in combination at any ratio.

The organic substance having a reactive functional group is particularly preferably an organic substance having an isocyanate group because the organic substance can improve stability between the metal oxide and surrounding substances. Examples of the organic substance having an isocyanate group may include acryloxymethyl isocyanate, methacryloxymethyl isocyanate, acryloxyethyl isocyanate, methacryloxyethyl isocyanate, acryloxypropyl isocyanate, methacryloxypropyl isocyanate, and 1,1-bis(acryloxymethyl)ethyl isocyanate. One type of these may be solely used, and two or more types thereof may also be used in combination at any ratio.

The content of the organic substance having a reactive functional group in the reactive modified metal oxide particles may be 1 part by weight to 40 parts by weight relative to 100 parts by weight of the metal oxide.

The reactive modified metal oxide particles may be obtained, as a suspension in which the particles are dispersed in an organic solvent, for example, by mixing metal oxide particles, an organic substance having a reactive functional group, the organic solvent, and as needed, an optional additive, and subjecting the resulting mixture to a treatment such as an ultrasonic treatment, as necessary.

Examples of the organic solvent may include a ketone solvent such as methyl ethyl ketone, methyl isobutyl ketone, acetone, and cyclohexanone; an aromatic hydrocarbon such as benzene, toluene, xylene, and ethyl benzene; an alcohol solvent such as methanol, ethanol, isopropyl alcohol, n-butanol, and iso-butanol; an ether solvent such as ethylene glycol monomethyl ether, ethylene glycol monoethyl ether, ethylene glycol monobutyl ether, diethylene glycol monomethyl ether, and diethylene glycol monoethyl ether; an ester solvent such as ethyl acetate, butyl acetate, ethyl lactate, γ-butyloactone, propylene glycol monomethyl ether acetate, and propylene glycol monoethyl ether acetate; and an amide solvent such as dimethylformamide, N,N-dimethylacetamide, and N-methylpyrrolidone. As the organic solvent, one type thereof may be solely used, and two or more types thereof may also be used in combination at any ratio.

Examples of the optional additive may include a metal chelating agent. As the additive, one type thereof may be solely used, and two or more types thereof may also be used in combination at any ratio.

When the reactive modified metal oxide particles are obtained as a suspension in which the particles are dispersed in an organic solvent, the resulting suspension as it is may preferably be supplied to the production of the adhesive resin from the viewpoint of simplicity of the production. In this case, the aforementioned suspension is preferably adjusted to contain the reactive modified metal oxide particles in an amount of 1% by weight to 50% by weight by adjusting conditions such as the amount of the solvent.

When they are mixed, it is preferable to use a mixer such as a ball mill. By such mixing, secondary particles or higher-order particles can be pulverized to a primary particle level, thereby allowing the surface in the state of primary particles to be treated. As a result, uniform surface treatment can be achieved.

It is further preferable that the mixture is subjected to an ultrasonic treatment as necessary. The ultrasonic treatment may be performed by using an instrument such as an ultrasonic washing machine, an ultrasonic homogenizer, and an ultrasonic disperser. Such a treatment can provide a favorable suspension.

As the reactive modified metal oxide particles, commercially available particles may be used as they are. Such commercially available particles may be supplied as a slurry containing components such as a solvent and an additive, and the particles in a slurry state containing these components as they are may be used as the material of the adhesive resin. Examples of the slurry of the reactive modified metal oxide particles containing ZrO₂ as the metal oxide may include trade name “NANON5 ZR-010” (manufactured by Solar Co., Ltd., solvent: methyl ethyl ketone, particle content: 30%, the organic substance having a reactive functional group that modifies the surface; an isocyanate having a polymerizable functional group, volume average particle diameter: 15 nm). Examples of the slurry of the reactive modified metal oxide particles containing TiO₂ as the metal oxide may include trade name “NOD-742GTF” (manufactured by Nagase ChemteX Corporation, solvent: polyethylene glycol monomethyl ether, particle content: 30%, volume average particle diameter: 48 nm).

As the aforementioned inorganic particles, one type thereof may be solely used, and two or more types thereof may also be used in combination at any ratio.

The volume average particle diameter of the inorganic particles is usually 5 nm or more, and preferably 10 nm or more, and is usually 50 nm or less, and preferably 20 nm or less. When the volume average particle diameter of the inorganic particles is equal to or less than the upper limit of the aforementioned range, the hygroscopic resin layer that is less colored and has high light transmittance can be obtained, and dispersion of the particles can be facilitated. When the inorganic particles are agglomerated to form secondary particles or higher-order particles, the range of the volume average particle diameter may be the range of the primary particle diameter. The volume average particle diameter may be measured using a dynamic light scattering particle distribution analyzer (“Nanotrac Wave-EX150” manufactured by Nikkiso Co., Ltd.) on the basis of volume serving as particle diameter basis.

The amount of the inorganic particles in the adhesive resin is preferably 130 parts by weight or more, more preferably 138 parts by weight or more, and particularly preferably 150 parts by weight or more, and is preferably 220 parts by weight or less, more preferably 212 parts by weight or less, and particularly preferably 195 parts by weight or less, relative to 100 parts by weight of the adhesive polymer. When the amount of the inorganic particles is equal to or more than the lower limit value of the aforementioned range, refractive index of the hygroscopic resin layer can be increased. When the amount thereof is equal to or less than the upper limit value of the aforementioned range, the hygroscopic resin layer can have high adhesiveness.

The adhesive resin may contain a plasticizer as an optional component. By the plasticizer, viscosity of the adhesive resin can be decreased and high adhesiveness thereof can be maintained. Specifically, when the adhesive resin contains particles such as the hygroscopic particles and inorganic particles, the adhesiveness thereof may decrease in some cases. Even in this case, if the adhesive resin contains a plasticizer, the adhesive resin even containing particles can maintain high adhesiveness.

The melting point of the plasticizer is preferably 0° C. or lower, and more preferably −10° C. or lower, is and preferably −70° C. or higher, and more preferably −60° C. or higher. When the melting point of the plasticizer falls within this range, the adhesive resin can have advantages such that the compatibility is excellent, there is no adhesive remaining on an adherend, and the adhesive resin has appropriate adhesiveness.

Examples of the plasticizer may include a polybutene, a vinyl ether compound, a polyether compound (including a polyalkylene oxide and a functionalized polyalkylene oxide), an ester compound, a polyol compound (e.g., glycerin), a petroleum resin, a hydrogenated petroleum resin, and a styrene-based compound (e.g., α-methylstyrene). Among these, from the viewpoint of favorable miscibility with the adhesive polymer and relatively high refractive index, an ester compound is preferable. In particular, an ester compound containing an aromatic ring, such as a benzoic acid-based compound and a phthalic acid-based compound, is preferable.

Examples of the benzoic acid ester usable as the plasticizer may include diethylene glycol dibenzoate, dipropylene glycol dibenzoate, benzyl benzoate, and 1,4-cyclohexane dimethanol dibenzoate. Among these, particularly preferable examples may include dipropylene glycol dibenzoate and benzyl benzoate.

Examples of the phthalic acid ester usable as the plasticizer may include dimethyl phthalate, diethyl phthalate, dibutyl phthalate, butylbenzyl phthalate, dicyclohexyl phthalate, and ethylphthalyl ethyl glycolate.

Examples of the commercially available plasticizer may include trade name “BENZOFLEX 9-88SG” (manufactured by Eastman Chemical Company), and trade name “α-methylstyrene” (manufactured by Mitsubishi Chemical Corporation).

As the plasticizer, one type thereof may be solely used, and two or more types thereof may also be used in combination at any ratio.

The amount of the plasticizer is preferably 5 parts by weight or more, and more preferably 10 parts by weight or more, and is preferably 20 parts by weight or less, and more preferably 15 parts by weight or less, relative to 100 parts by weight of the adhesive polymer.

The adhesive resin may contain a silane coupling agent as an optional component. Examples of the silane coupling agent may include vinyltrimethoxysilane, vinyltriethoxysilane, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethyoxysilane, p-styryltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, 3-acryloxypropyltrimethoxysilane, N-2-(aminoethyl)-3-aminopropylmethyldimethoxysilane, N-2-(aminoethyl)-3-aminopropyltrimethoxysilane, N-2-(aminoethyl)-3-aminopropyltriethoxysilane, 3-aminopropyltrimethoxysilane, 3-aminopropyltriethoxysilane, 3-triethoxysilyl-N-(1,3-dimethyl-butylidene)propylamine, N-phenyl-3-aminopropyltrimethoxysilane, 3-ureidopropyltriethoxysilane, 3-mercaptopropyl methyldimethoxysilane, 3-mercaptopropyltrimethoxysilane, bis(triethoxysilylpropyl)tetrasulfide, and 3-isocyanatopropyltriethoxysilane.

Examples of the commercially available silane coupling agent may include trade name “KBM-803” (manufactured by Shin-Etsu Chemical Co., Ltd.).

As the silane coupling agent, one type thereof may be solely used, and two or more types thereof may also be used in combination at any ratio.

The amount of the silane coupling agent is preferably 0.05 parts by weight or more, and more preferably 0.1 parts by weight or more, and is preferably 5 parts by weight or less, and more preferably 3 parts by weight or less, relative to 100 parts by weight of the adhesive polymer.

The adhesive resin may contain a curing agent as an optional component. Examples of the curing agent may include an isocyanate-based compound. Specific examples of the curing agent may include an addition polymer of isocyanate containing isophorone diisocyanate (e.g., trade name “NY-260A” manufactured by Mitsubishi Chemical Corporation). As the curing agent, one type thereof may be solely used, and two or more types thereof may also be used in combination at any ratio.

The amount of the curing agent is preferably 0.01 parts by weight or more, and more preferably 0.05 parts by weight or more, and is preferably 5 parts by weight or less, and more preferably 1 part by weight or less, relative to 100 parts by weight of the adhesive polymer.

The adhesive resin may contain light scattering particles other than the above-described hygroscopic particles and inorganic particles as an optional component. Examples of an organic material constituting the light scattering particles may include a silicone resin, an acrylic resin, and a polystyrene resin. The particle diameter of the light scattering particles is preferably 0.2 μm or more, and more preferably 0.5 μm or more, and is preferably 5 μm or less, and more preferably 3 μm or less.

Examples of the commercially available light scattering particles of which material is a silicone resin may include trade name “XC-99” (manufactured by Momentive Performance Materials Inc., volume average particle diameter: 0.7 μm). Examples of the commercially available light scattering particles of which material is an acrylic resin may include trade name “MP series” (manufactured by Soken Chemical & Engineering Co., Ltd., volume average particle diameter: 0.8 μm). Examples of the commercially available light scattering particles of which material is a polystyrene resin may include trade name “SX series” (manufactured by Soken Chemical & Engineering Co., Ltd., volume average particle diameter: 3.5 μm).

(3.2.2. Thermoplastic Elastomer Resin)

The thermoplastic elastomer resin is a resin containing a thermoplastic elastomer. The thermoplastic elastomer is a polymer having rubber elasticity at room temperature even without vulcanization. The “room temperature” herein usually refers to 25° C. At high temperature, the thermoplastic elastomer resin can be molded using an existing molding machine like a common thermoplastic resin. Therefore, the thermoplastic elastomer resin generally contains no residual solvent, or contains a very small amount of a solvent. So, the hygroscopic resin layer containing the thermoplastic elastomer resin can reduce outgas, and thus achieve high gas barrier property.

Examples of the thermoplastic elastomer may include a styrene-based thermoplastic elastomer, an olefin-based thermoplastic elastomer, a vinyl chloride-based thermoplastic elastomer, a polyester-based thermoplastic elastomer, and a urethane-based thermoplastic elastomer. Among these, a styrene-based thermoplastic elastomer is preferable. The styrene-based thermoplastic elastomer is a thermoplastic elastomer having an aromatic vinyl compound unit as a structural unit of the molecule. The aromatic vinyl compound unit herein refers to a structural unit having a structure formed by polymerizing an aromatic vinyl compound such as styrene. The thermoplastic elastomer generally has a rubber component having elasticity (i.e., a soft segment), and a molecular restraint component for preventing plastic deformation (i.e., a hard segment) in its molecule. The styrene-based thermoplastic elastomer usually has the aforementioned aromatic vinyl compound unit as the hard segment.

Preferable examples of the styrene-based thermoplastic elastomer may include an aromatic vinyl compound-conjugated diene block copolymer and a hydrogenated product thereof. The aromatic vinyl compound-conjugated diene block copolymer herein refers to a block copolymer having a polymer block [A] containing an aromatic vinyl compound unit and a polymer block [B] containing a chain conjugated diene compound unit. The chain conjugated diene compound unit refers to a structural unit having a structure formed by polymerizing a chain conjugated diene compound. These block copolymer and hydrogenated product thereof may be modified by, for example, an alkoxysilane, a carboxylic acid, and a carboxylic acid anhydride.

Among these, an aromatic vinyl compound-conjugated diene block copolymer using styrene as the aromatic vinyl compound (hereinafter, which may be appropriately referred to as “styrene-conjugated diene block copolymer”) and a hydrogenated product thereof are preferable. A hydrogenated product of the styrene-conjugated diene block copolymer is particularly preferable. In the following, the aromatic vinyl compound-conjugated diene block copolymer and hydrogenated product thereof will be specifically described.

As described above, the polymer block [A] includes an aromatic vinyl compound unit. Examples of an aromatic vinyl compound corresponding to the aromatic vinyl compound unit may include styrene, α-methylstyrene, 2-methylstyrene, 3-methylstyrene, 4-methylstyrene, 2,4-diisopropylstyrene, 2,4-dimethylstyrene, 4-t-butylstyrene, 5-t-butyl-2-methylstyrene, 4-monochlorostyrene, dichlorostyrene, 4-monofluorostyrene, and 4-phenylstyrene. One type of these may be solely used, and two or more types thereof may also be used in combination at any ratio. Among these, those containing no polar group are preferable from the viewpoint of hygroscopicity. Further, from the viewpoint of industrial availability and impact resistance thereof, styrene is particularly preferable.

In the polymer block [A], the aromatic vinyl compound unit is usually the main component thereof. Specifically, the content ratio of the aromatic vinyl compound unit in the polymer block [A] is preferably 90% by weight or more, more preferably 95% by weight or more, and particularly preferably 99% by weight or more. When the polymer block [A] contains the large amount of the aromatic vinyl compound unit as described above, heat resistance of the hygroscopic resin layer can be increased.

The polymer block [A] may contain an optional structural unit other than the aromatic vinyl compound unit. Examples of the optional structural unit may include a chain conjugated diene compound unit, and a structural unit having a structure formed by polymerizing a vinyl compound other than the aromatic vinyl compound.

Examples of a chain conjugated diene compound corresponding to the chain conjugated diene compound unit may include 1,3-butadiene, isoprene, 2,3-dimethyl-1,3-butadiene, and 1,3-pentadiene. One type of these may be solely used, and two or more types thereof may also be used in combination at any ratio. Among these, those containing no polar group are preferable from the viewpoint of hygroscopicity. Specifically, 1,3-butadiene and isoprene are particularly preferable.

Examples of the vinyl compound other than the aromatic vinyl compound may include a chain vinyl compound; a cyclic vinyl compound; a vinyl compound having a nitrile group, an alkoxycarbonyl group, a hydroxycarbonyl group, or a halogen group; an unsaturated cyclic acid anhydride; and an unsaturated imide compound. Preferable examples thereof may include those having no polar group, such as chain olefins including ethylene, propylene, 1-butene, 1-pentene, 1-hexene, 1-heptene, 1-octene, 1-nonene, 1-decene, 1-dedecene, 1-eicocene, 4-methyl-1-pentene, 4,6-dimethyl-1-heptene, and the like; and cyclic olefins including vinyl cyclohexane and the like, from the viewpoint of hygroscopicity. Among these, chain olefins are more preferable, and ethylene and propylene are particularly preferable. One type of these may be solely used, and two or more types thereof may also be used in combination at any ratio.

The content ratio of the optional structural unit in the polymer block [A] is preferably 10% by weight or less, more preferably 5% by weight or less, and particularly preferably 1% by weight or less.

The number of the polymer block [A] in the aromatic vinyl compound-conjugated diene block copolymer is preferably 2 or more, and is preferably 5 or less, more preferably 4 or less, and particularly preferably 3 or less. A plurality of polymer blocks [A] may be the same as or different from one another.

When a plurality of different polymer blocks [A] are present in one molecule of the aromatic vinyl compound-conjugated diene block copolymer, the weight-average molecular weight of a polymer block having a maximum weight-average molecular weight in the polymer blocks [A] is represented by Mw(A1) and the weight-average molecular weight of a polymer block having a minimum weight-average molecular weight in the polymer blocks [A] is represented by Mw(A2). In this case, a ratio “Mw(A1)/Mw(A2)” of Mw(A1) to Mw(A2) is preferably 2.0 or less, more preferably 1.5 or less, and particularly preferably 1.2 or less. By setting the ratio in this manner, variation in various property values can be suppressed in small ranges.

As described above, the polymer block [B] contains the chain conjugated diene compound unit.

Examples of the chain conjugated diene compound unit may include those exemplified as the units that may be contained in the polymer block [A].

In the polymer block [B], the chain conjugated diene compound unit is usually the main component thereof. Specifically, the content ratio of the chain conjugated diene compound unit in the polymer block [B] is preferably 90% by weight or more, more preferably 95% by weight or more, and particularly preferably 99% by weight or more. When the polymer block [B] contains the large amount of the chain conjugated diene compound unit as described above, impact resistance of the hygroscopic resin layer at low temperatures can be improved.

The polymer block [B] may contain an optional structural unit other than the chain conjugated diene compound unit. Examples of the optional structural unit may include an aromatic vinyl compound unit, and a structural unit having a structure formed by polymerizing a vinyl compound other than the aromatic vinyl compound. Examples of the aromatic vinyl compound unit and the structural unit having a structure formed by polymerizing a vinyl compound other than the aromatic vinyl compound may include those exemplified as the units that may be contained in the polymer block [A].

The content ratio of the optional structural unit in the polymer block [B] is preferably 10% by weight or less, more preferably 5% by weight or less, and particularly preferably 1% by weight or less. In particular, when the content ratio of the aromatic vinyl compound unit in the polymer block [B] becomes low, flexibility of the hygroscopic resin layer at low temperatures can be improved and impact resistance thereof at low temperatures can be improved.

The number of the polymer block [B] in the aromatic vinyl compound-conjugated diene block copolymer is usually 1 or more, and may be 2 or more. When the number of the polymer block [B] in the aromatic vinyl compound-conjugated diene block copolymer is 2 or more, the polymer blocks [B] may be the same as or different from one another.

When a plurality of different polymer blocks [B] are present in one molecule of the aromatic vinyl compound-conjugated diene block copolymer, the weight-average molecular weight of a polymer block having a maximum weight-average molecular weight in the polymer blocks [B] is represented by Mw(B1) and the weight-average molecular weight of a polymer block having a minimum weight-average molecular weight in the polymer blocks [B] is represented by Mw(B2). In this case, a ratio “Mw(B1)/Mw(B2)” of Mw(B1) to Mw(B2) is preferably 2.0 or less, more preferably 1.5 or less, and particularly preferably 1.2 or less. By setting the ratio in this manner, variation in various property values can be suppressed in small ranges.

The form of the block of the aromatic vinyl compound-conjugated diene block copolymer may be a chain block or radial block. Of these, a chain block is preferable because of excellent mechanical strength. When the aromatic vinyl compound-conjugated diene block copolymer has the form of the chain block, it is preferable that the both ends thereof are the polymer blocks [A] because stickiness of the resin can thereby be suppressed to a desired low value.

The particularly preferable form of the aromatic vinyl compound-conjugated diene block copolymer may include a triblock copolymer represented by [A]-[B]-[A] in which the polymer blocks [A] are bonded to both ends of the polymer block [B]; and a pentablock copolymer represented by [A]-[B]-[A]-[B]-[A] in which the polymer blocks [B] are bonded to both ends of the polymer block [A] and polymer blocks [A] are further bonded to both of the other ends of the polymer blocks [B].

In the aromatic vinyl compound-conjugated diene block copolymer, the weight fraction of the total polymer blocks [A] in the entire aromatic vinyl compound-conjugated diene block copolymer is represented by wA, and the weight fraction of the total polymer blocks [B] in the entire aromatic vinyl compound-conjugated diene block copolymer is represented by wB. In this case, a ratio (wA/wB) of wA to wB is preferably 20/80 or more, more preferably 35/63 or more, and particularly preferably 40/60 or more, and is preferably 80/20 or less, more preferably 65/35 or less, and particularly preferably 60/40 or less. When the wA/wB is equal to or more than the lower limit value of the aforementioned range, heat resistance of the hygroscopic resin layer can be improved. When the wA/wB is equal to or less than the upper limit value of the aforementioned range, flexibility of the hygroscopic resin layer can be enhanced and gas barrier property can be stably and favorably maintained.

The weight-average molecular weight of the aromatic vinyl compound-conjugated diene block copolymer is preferably 30,000 or more, more preferably 40,000 or more, and particularly preferably 50,000 or more, and is preferably 200,000 or less, more preferably 150,000 or less, and particularly preferably 100,000 or less.

The molecular weight distribution (Mw/Mn) of the aromatic vinyl compound-conjugated diene block copolymer is preferably 3 or less, more preferably 2 or less, and particularly preferably 1.5 or less.

The weight-average molecular weight and the molecular weight distribution mentioned above may be measured as a polystyrene-equivalent value by gel permeation chromatography using tetrahydrofuran (THF) as a solvent.

For example, when a block copolymer having three polymer blocks is to be produced, examples of the method for producing the aromatic vinyl compound-conjugated diene block copolymer may include the following production methods 1 and 2. A material referred to herein as “monomer composition” encompasses not only a mixture of two or more types of substances, but also a material comprising a single substance.

(Production Method 1) A method including:

a first step of polymerizing a monomer composition (a1) containing an aromatic vinyl compound to form a polymer block [A];

a second step of polymerizing a monomer composition (b1) containing a chain conjugated diene compound at one end of the polymer block [A] to form a polymer block B, thereby obtaining a polymer of diblock [A]-[B]; and

a third step of polymerizing a monomer composition (a2) containing an aromatic vinyl compound at an end of the polymer of the diblock on the block [B] side to obtain a block copolymer. The monomer compositions (a1) and (a2) may be the same as or different from each other.

(Production Method 2) A method including:

a first step of polymerizing a monomer composition (a1) containing an aromatic vinyl compound to form a polymer block [A];

a second step of polymerizing a monomer composition (b1) containing a chain conjugated diene compound at one end of the polymer block [A] to form a polymer block B, thereby obtaining a polymer of diblock [A]-[B]; and

a third step of coupling both ends of the polymer of the diblock on the polymer block [B] side by a coupling agent to obtain a block copolymer.

Examples of the method for obtaining respective polymer blocks by polymerizing a monomer mixture may include radical polymerization, anionic polymerization, cationic polymerization, coordination anionic polymerization, and coordination cationic polymerization. From the viewpoint of facilitating the polymerization operation and the hydrogenation reaction in the later step, a method of performing radical polymerization, anionic polymerization, or cationic polymerization by living polymerization is preferable, and a method of performing polymerization by living anionic polymerization is particularly preferable.

The polymerization of the aforementioned monomer mixture is performed in the presence of a polymerization initiator in a temperature range of preferably 0° C. or higher, more preferably 10° C. or higher, and particularly preferably 20° C. or higher, and preferably 100° C. or lower, more preferably 80° C. or lower, and particularly preferably 70° C. or lower.

When living anionic polymerization is adopted, examples of the polymerization initiator may include monoorganolithium such as n-butyllithium, sec-butyllithium, t-butyllithium, and hexyllithium; and a polyfunctional organolithium compound such as dilithiomethane, 1,4-dilithiobutane, and 1,4-dilithio-2-ethylcyclohexane. One type of these may be solely used, and two or more types thereof may also be used in combination at any ratio.

Examples of the system of the polymerization reaction to be adopted may include solution polymerization and slurry polymerization. Of these, when solution polymerization is used, heat of reaction is easily removed.

When the solution polymerization is performed, an inert solvent that can dissolve polymers obtained in respective steps may be used as the solvent. Examples of the inert solvent may include aliphatic hydrocarbons such as n-pentane, isopentane, n-hexane, n-heptane, and isooctane; alicyclic hydrocarbons such as cyclopentane, cyclohexane, methylcyclopentane, methylcyclohexane, and decalin; and aromatic hydrocarbons such as benzene and toluene. One type of these may be solely used, and two or more types thereof may also be used in combination at any ratio. Of these, when an alicyclic hydrocarbon is used as a solvent, the alicyclic hydrocarbon as it is can be used also in the hydrogenation reaction as an inert solvent, and the solubility of the aromatic vinyl compound-conjugated diene block copolymer is favorable, and thus it is preferable. The using amount of the solvent is usually 200 parts by weight to 2,000 parts by weight relative to 100 parts by weight of the total of the used monomers.

When each of the monomer mixtures contains two or more types of monomers, for example, a randomizer may be used to prevent a chain of one component from being excessively elongated. In particular, when the polymerization reaction is anionic polymerization, it is preferable to use a Lewis base compound as the randomizer, for example. Examples of the Lewis base compound may include an ether compound such as dimethyl ether, diethyl ether, diisopropyl ether, dibutyl ether, tetrahydrofuran, diphenyl ether, ethylene glycol diethyl ether, and ethylene glycol methyl phenyl ether; a tertiary amine compound such as tetramethylethylenediamine, trimethylamine, triethylamine, and pyridine; an alkali metal alkoxide compound such as potassium-t-amyloxide and potassium-t-butyloxide; and a phosphine compound such as triphenyl phosphine. One type of these may be solely used, and two or more types thereof may also be used in combination at any ratio.

It is preferable to use the aforementioned aromatic vinyl compound-conjugated diene block copolymer that has been hydrogenated. When the hygroscopic resin layer contains the thermoplastic elastomer resin containing the hydrogenated product of the aromatic vinyl compound-conjugated diene block copolymer, the amount of outgas generated from the hygroscopic resin layer can be further reduced.

The hydrogenated product of the aromatic vinyl compound-conjugated diene block copolymer is a product obtained by hydrogenating the carbon-carbon unsaturated bonds in the main chain and the side chain of the aromatic vinyl compound-conjugated diene block copolymer. The aforementioned carbon-carbon unsaturated bond herein includes both aromatic and non-aromatic carbon-carbon unsaturated bonds. The hydrogenation rate is preferably 90% or more, more preferably 97% or more, and particularly preferably 99% or more. As the hydrogenation rate is higher, heat resistance and light resistance of the hygroscopic resin layer can be made favorable. The hydrogenation rate of the hydrogenated product may be determined by ¹H-NMR measurement.

In particular, the hydrogenation rate of the non-aromatic carbon-carbon unsaturated bond is preferably 95% or more, and more preferably 99% or more. By increasing the hydrogenation rate of the non-aromatic carbon-carbon unsaturated bond, light resistance and oxidation resistance of the hygroscopic resin layer can be further enhanced.

The hydrogenation rate of the aromatic carbon-carbon unsaturated bond is preferably 90% or more, more preferably 93% or more, and particularly preferably 95% or more. By increasing the hydrogenation rate of the aromatic carbon-carbon unsaturated bond, glass transition temperature of the polymer block obtained by hydrogenating the polymer block [A] can be increased, and thus heat resistance of the hygroscopic resin layer can be effectively enhanced.

The weight-average molecular weight (Mw) of the hydrogenated product of the aromatic vinyl compound-conjugated diene block copolymer is preferably 30,000 or more, more preferably 40,000 or more, and particularly preferably 45,000 or more, and is preferably 200,000 or less, more preferably 150,000 or less, and particularly preferably 100,000 or less. The molecular weight distribution (Mw/Mn) of the hydrogenated product of the aromatic vinyl compound-conjugated diene block copolymer is preferably 3 or less, more preferably 2 or less, and particularly preferably 1.5 or less. When the weight-average molecular weight Mw and the molecular weight distribution Mw/Mn of the hydrogenated product of the aromatic vinyl compound-conjugated diene block copolymer fall within the aforementioned ranges, mechanical strength and heat resistance of the hygroscopic resin layer can be improved. The weight-average molecular weight and the molecular weight distribution of the aforementioned hydrogenated product of the block copolymer may be measured as a polystyrene-equivalent value by gel permeation chromatography using tetrahydrofuran as a solvent.

In the hydrogenated product of the aromatic vinyl compound-conjugated diene block copolymer, a ratio (wA/wB) of the weight fraction wA of the total polymer blocks [A] in the entire block copolymer to the weight fraction wB of the total polymer blocks [B] in the entire block copolymer is usually the same value as that of the ratio wA/wB in the block copolymer before it is hydrogenated.

The hydrogenated product of the aromatic vinyl compound-conjugated diene block copolymer may further have an alkoxysilyl group in its molecular structure. The hydrogenated product of the aromatic vinyl compound-conjugated diene block copolymer having such an alkoxysilyl group is obtained by, for example, introducing an alkoxysilyl group into the hydrogenated product of the block copolymer having no alkoxysilyl group. When an alkoxysilyl group is introduced, the alkoxysilyl group may be directly bonded to the hydrogenated product of the block copolymer, or may be bonded thereto via a divalent organic group such as an alkylene group.

The thermoplastic elastomer resin containing the hydrogenated product of the aromatic vinyl compound-conjugated diene block copolymer having an alkoxysilyl group is particularly excellent in adhesiveness. Accordingly, adhesiveness of the hygroscopic resin layer can be remarkably increased.

The amount of the alkoxysilyl group introduced is preferably 0.1 parts by weight or more, more preferably 0.2 parts by weight or more, and particularly preferably 0.3 parts by weight or more, and is preferably 10 parts by weight or less, more preferably 5 parts by weight or less, and particularly preferably 3 parts by weight or less, relative to 100 parts by weight of the hydrogenated product of the aromatic vinyl compound-conjugated diene block copolymer before the introduction of the alkoxysilyl group. When the amount of the alkoxysilyl group introduced falls within the aforementioned range, it is possible to prevent the cross-linking degree between the alkoxysilyl groups decomposed by, for example, moisture from becoming excessively high, thereby maintaining high adhesiveness of the hygroscopic resin layer.

The amount of the alkoxysilyl group introduced may be measured by ¹H-NMR spectrometry. If the amount of the alkoxysilyl group introduced is small, the measurement of the amount of the alkoxysilyl group introduced may be performed by increasing the cumulated number.

Since the amount of the alkoxysilyl group introduced is usually small, the molecular weight of the hydrogenated product of the aromatic vinyl compound-conjugated diene block copolymer having an alkoxysilyl group does not so largely change from that of the hydrogenated product of the block copolymer before introduction of the alkoxysilyl group. However, since the hydrogenated product of the aromatic vinyl compound-conjugated diene block copolymer is subjected to modification reaction in the presence of a peroxide during the introduction of an alkoxysilyl group, there is a tendency that crosslinking reaction and cleavage reaction of the hydrogenated product proceed, and thus the molecular weight distribution changes largely. The weight-average molecular weight of the hydrogenated product of the aromatic vinyl compound-conjugated diene block copolymer having an alkoxysilyl group is preferably 30,000 or more, more preferably 40,000 or more, and particularly preferably 50,000 or more, and is preferably 200,000 or less, more preferably 150,000 or less, and particularly preferably 120,000 or less. The molecular weight distribution (Mw/Mn) of the hydrogenated product of the aromatic vinyl compound-conjugated diene block copolymer having an alkoxysilyl group is preferably 3.5 or less, more preferably 2.5 or less, and particularly preferably 2.0 or less. When the weight-average molecular weight Mw and the molecular weight distribution Mw/Mn of the hydrogenated product of the aromatic vinyl compound-conjugated diene block copolymer having an alkoxysilyl group fall within the aforementioned ranges, favorable mechanical strength and tensile elongation of the hygroscopic resin layer can be maintained. The weight-average molecular weight and the molecular weight distribution of the aforementioned hydrogenated product of the aromatic vinyl compound-conjugated diene block copolymer having an alkoxysilyl group may be measured as a polystyrene-equivalent value by gel permeation chromatography using tetrahydrofuran as a solvent.

The method for producing the hydrogenated product of the aromatic vinyl compound-conjugated diene block copolymer as described above usually includes hydrogenation of the aforementioned aromatic vinyl compound-conjugated diene block copolymer. As the hydrogenation method, a hydrogenation method that can increase the hydrogenation rate and suppress chain cleavage reaction of the block copolymer is preferable. Examples of such a preferable hydrogenation method may include a method of performing hydrogenation using a hydrogenation catalyst containing at least one type of metal selected from the group consisting of nickel, cobalt, iron, titanium, rhodium, palladium, platinum, ruthenium, and rhenium. The hydrogenation catalyst for use may be any of a heterogeneous catalyst and a homogeneous catalyst. It is preferable to perform the hydrogenation reaction in an organic solvent.

As the heterogeneous catalyst, a metal or a metal compound as it is may be used. Alternatively, the metal or metal compound supported on a suitable carrier may also be used. Examples of the carrier may include activated carbon, silica, alumina, calcium carbide, titania, magnesia, zirconia, diatomaceous earth, silicon carbide, and calcium fluoride. The amount of the catalyst to be supported on the carrier is preferably 0.1% by weight or more, and more preferably 1% by weight or more, and is preferably 60% by weight or less, and more preferably 50% by weight or less, relative to the total amount of the catalyst and carrier. The specific surface area of the carrier-type catalyst is preferably 100 m²/g to 500 m²/g. The average pore size of the carrier-type catalyst is 100 Å or more, more preferably 200 Å or more, and is preferably 1000 Å or less, and preferably 500 Å or less. The specific surface area may be determined by measuring the adsorbed amount of nitrogen and using the BET formula. The average pore size may be measured by the mercury intrusion technique.

Examples of the homogeneous catalyst may include a catalyst including a compound of nickel, cobalt, titanium, or iron in combination with an organometallic compound; and an organometallic complex catalyst of rhodium, palladium, platinum, ruthenium, or rhenium.

Examples of the compound of nickel, cobalt, titanium, or iron may include an acetylacetonato compound, a carboxylic acid salt, and a cyclopentadienyl compound of each metal.

Examples of the organometallic compound may include organoaluminum compounds such as alkyl aluminum, e.g., triethyl aluminum and triisobutyl aluminum, halogenated aluminum, e.g., diethyl aluminum chloride and ethyl aluminum dichloride, and hydrogenated alkyl aluminum, e.g., diisobutyl aluminum hydride; and organolithium compounds.

Examples of the organometallic complex catalyst may include a transition metal complex, e.g., dihydride-tetrakis(triphenylphosphine)ruthenium, dihydride-tetrakis(triphenylphosphine)iron, bis(cyclooctadiene)nickel, and bis(cyclopentadienyl)nickel.

As the hydrogenation catalyst, one type thereof may be solely used, and two or more types thereof may also be used in combination at any ratio.

The using amount of the hydrogenation catalyst is preferably 0.01 parts by weight or more, more preferably 0.05 parts by weight or more, and particularly preferably 0.1 parts by weight or more, and is preferably 100 parts by weight or less, more preferably 50 parts by weight or less, and particularly preferably 30 parts by weight or less, relative to 100 parts by weight of the aromatic vinyl compound-conjugated diene block copolymer.

The temperature during the hydrogenation reaction is preferably 10° C. or higher, more preferably 50° C. or higher, and particularly preferably 80° C. or higher, and is preferably 250° C. or lower, more preferably 200° C. or lower, and particularly preferably 180° C. or lower. When the hydrogenation reaction is performed within such a temperature range, hydrogenation rate can be increased, and molecular cleavage of the block copolymer can be suppressed.

The hydrogen pressure during the hydrogenation reaction is preferably 0.1 MPa or more, more preferably 1 MPa or more, and particularly preferably 2 MPa or more, and is preferably 30 MPa or less, more preferably 20 MPa or less, and particularly preferably 10 MPa or less. When the hydrogenation reaction is performed at such a hydrogen pressure, hydrogenation rate can be increased, molecular cleavage of the block copolymer can be suppressed, and favorable operability can be achieved.

When the aromatic vinyl compound-conjugated diene block copolymer is hydrogenated as described above, the hydrogenated product of the aromatic vinyl compound-conjugated diene block copolymer can be obtained as the product. The hydrogenated product is usually obtained as a reaction liquid containing the hydrogenated product of the block copolymer, the hydrogenation catalyst, and the polymerization catalyst. Thus, the hydrogenated product of the block copolymer may be collected from the reaction liquid after the hydrogenation catalyst and the polymerization catalyst are removed from the reaction liquid by a separation method, such as filtration or centrifugal separation. Examples of the method for collecting the hydrogenated product from the reaction liquid may include a steam coagulation method of removing a solvent from a solution, in which the hydrogenated product is dissolved, by steam stripping; a direct desolvation method of removing a solvent under reduced pressure and heating; and a coagulation method of precipitating and coagulating the hydrogenated product by pouring the solution into a poor solvent for the hydrogenated product.

The form of the collected hydrogenated product of the aromatic vinyl compound-conjugated diene block copolymer is preferably in the form of pellet so that the hydrogenated product can be easily supplied to the following molding process and modification reaction. For example, when the hydrogenated product is collected from the reaction liquid by a direct desolvation method, the hydrogenated product in a molten state is extruded through a die into a strand shape, cooled, and then cut by a pelletizer to form pellets to be supplied to various molding processes. When a coagulation method is used, the resulting coagulated product may be dried, and the product in a molten state may be extruded by an extruder to form pellets as described above, to be supplied to various molding processes or modification reaction.

As necessary, the hydrogenated product of the aromatic vinyl compound-conjugated diene block copolymer that is obtained by hydrogenation reaction may be subjected to modification treatment by an alkoxy silane. The modification treatment above can introduce an alkoxysilyl group into the hydrogenated product of the aromatic vinyl compound-conjugated diene block copolymer.

As the method for introducing an alkoxysilyl group, for example, a method in which the hydrogenated product of the aromatic vinyl compound-conjugated diene block copolymer before introducing the alkoxysilyl group and an ethylenic unsaturated silane compound are reacted in the presence of a peroxide may be used.

As the ethylenic unsaturated silane compound, those capable of being graft-polymerized with the hydrogenated product of the aromatic vinyl compound-conjugated diene block copolymer and of introducing an alkoxysilyl group into the hydrogenated product of the aromatic vinyl compound-conjugated diene block copolymer may be used. Examples of such an ethylenic unsaturated silane compound may include vinyltrimethoxysilane, vinyltriethoxysilane, allyltrimethoxysilane, allyltriethoxysilane, dimethoxymethylvinylsilane, diethoxymethylvinylsilane, p-styryltrimethoxysilane, p-styryltriethoxysilane, 3-methacryloxypropyltrimethoxysilane, 3-methacryloxypropylmethyldimethoxysilane, 3-methacryloxypropyltriethoxysilane, 3-methacryloxypropylmethyldiethoxysilane, 3-acryloxypropyltrimethoxysilane, 3-acryloxypropyltriethoxysilane, and 2-norbornen-5-yltrimethoxysilane. Among these, vinyltrimethoxysilane, vinyltriethoxysilane, allyltrimethoxysilane, allyltriethoxysilane, dimethoxymethylvinylsilane, diethoxymethylvinylsilane, and p-styryltrimethoxysilane are preferable. As the ethylenic unsaturated silane compound, one type thereof may be solely used, and two or more types thereof may also be used in combination at any ratio.

The amount of the ethylenic unsaturated silane compound is preferably 0.1 parts by weight or more, more preferably 0.2 parts by weight or more, and particularly preferably 0.3 parts by weight or more, and is preferably 10 parts by weight or less, more preferably 5 parts by weight or less, and particularly preferably 3 parts by weight or less, relative to 100 parts by weight of the hydrogenated product of the block copolymer before the introduction of the alkoxysilyl group.

As the peroxide, one or more types selected from organic peroxides, e.g., dibenzoyl peroxide, t-butylperoxyacetate, 2,2-di-(t-butylperoxy)butane, t-butylperoxybenzoate, t-butylcumyl peroxide, dicumyl peroxide, di-t-hexyl peroxide, 2,5-dimethyl-2,5-di(t-butylperoxyhexane), di-t-butyl peroxide, 2,5-dimethyl-2,5-di(t-butylperoxy)hexane-3, t-butyl hydroperoxide, t-butylperoxyisobutyrate, lauloyl peroxide, dipropionyl peroxide, p-menthane hydroperoxide, and the like may be used. Among these, those having a 1-minute half-life temperature of 170° C. to 190° C. are preferable. For example, t-butylcumyl peroxide, dicumyl peroxide, di-t-hexyl peroxide, 2,5-dimethyl-2,5-di(t-butylperoxyhexane), di-t-butyl peroxide, and the like are preferable. As the peroxide, one type thereof may be solely used, and two or more types thereof may also be used in combination at any ratio.

The amount of the peroxide is preferably 0.01 parts by weight or more, more preferably 0.2 parts by weight or more, and particularly preferably 0.3 parts by weight or more, and is preferably 5 parts by weight or less, more preferably 3 parts by weight or less, and particularly preferably 2 parts by weight or less, relative to 100 parts by weight of the hydrogenated product of the aromatic vinyl compound-conjugated diene block copolymer before the introduction of the alkoxysilyl group.

The method for reacting the aforementioned hydrogenated product of the aromatic vinyl compound-conjugated diene block copolymer and the ethylenic unsaturated silane compound in the presence of a peroxide may be performed using, for example, a heating and kneading machine and a reactor vessel. As a specific example, a mixture of the hydrogenated product of the block copolymer, an ethylenic unsaturated silane compound, and a peroxide are heated and melted by using a twin-screw kneader at or higher than the melting temperature of the hydrogenated product of the block copolymer to be kneaded for a desired time period. Thereby the alkoxysilyl group can be introduced into the hydrogenated product of the block copolymer. The specific temperature during kneading is preferably 180° C. or higher, more preferably 190° C. or higher, and particularly preferably 200° C. or higher, and is preferably 240° C. or lower, more preferably 230° C. or lower, and particularly preferably 220° C. or lower. The kneading time is preferably 0.1 minutes or more, more preferably 0.2 minutes or more, and particularly preferably 0.3 minutes or more, and is preferably 15 minutes or less, more preferably 10 minutes or less, and particularly preferably 5 minutes or less. When continuous kneading facilities such as a twin-screw extruder, a single-screw extruder, and the like are used, kneading and extruding may be continuously performed so that the residence time falls within the aforementioned range.

The thermoplastic elastomer resin may further contain an optional component in combination with the above-described hygroscopic particles and polymer. Examples of the optional component may include a light stabilizer, an ultraviolet absorber, an antioxidant, a lubricant, and an inorganic filler, which are for improving weather resistance and heat resistance. One type of these may be solely used, and two or more types thereof may also be used in combination at any ratio.

As the light stabilizer, a hindered amine-based light stabilizer is preferable. Compounds having, for example, a 3,5-di-t-butyl-4-hydorxyphenyl group, a 2,2,6,6-tetramethylpyperidyl group, or a 1,2,2,6,6-pentamethyl-4-piperidyl group in its structure are particularly preferable.

Among these, from the viewpoint of excellent weather resistance, N,N′-bis(2,2,6,6-tetramethyl-4-N-methylpiperidyl)-N,N′-diformyl-alkylene diamines, N,N′-bis(2,2,6,6-tetramethyl-4-piperydyl)-N,N′-diformylalkylene diamines, N,N′-bis(2,2,6,6-tetramethyl-4-piperidyl)-N,N′-bisalkylene fatty acid amides, and poly[{6-(1,1,3,3-tetramethylbutyl)amino-1,3,5-triadine-2,4-diyl}{(2,2,6,6-tetramethyl-4-piperidyl)imino}hexamethylene{(2,2,6,6-tetramethyl-4-piperidyl)imino}] are preferable. N,N′-bis(2,2,6,6-tetramethyl-4-piperidyl)-N,N′-diformylalkylene diamines, and a reaction product of a polymer of N,N′-bis(2,2,6,6-tetramethyl-4-piperydyl)-1,6-hexanediamine and 2,4,6-trichloro-1,3,5-triazine with N-butyl-1-butane amine and N-butyl-2,2,6,6-tetramethyl-4-piperidynamine are particularly preferable.

The amount of the light stabilizer is preferably 0.01 parts by weight or more, more preferably 0.02 parts by weight or more, and particularly preferably 0.03 parts by weight or more, and is preferably 5 parts by weight or less, more preferably 2 parts by weight or less, and particularly preferably 1 part by weight or less, relative to 100 parts by weight of the thermoplastic elastomer. When the amount of the light stabilizer is equal to or more than the lower limit value of the aforementioned range, weather resistance can be increased. When the amount thereof is equal to or less than the upper limit value, a T-die and a cooling roller of an extruder can be prevented from being soiled during melt molding processing in which the thermoplastic elastomer resin is molded into a film shape. Thus, processability can be increased.

Examples of the ultraviolet absorber may include a benzophenone-based ultraviolet absorber, a salicylic acid-based ultraviolet absorber, and a benzotriazole-based ultraviolet absorber.

Examples of the benzophenone-based ultraviolet absorber may include 2,4-dihydroxybenzophenone, 2-hydroxy-4-methoxybenzophenone, 2-hydroxy-4-methoxybenzophenone-5-sulfonic acid trihydrate, 2-hydroxy-4-octyloxybenzophenone, 4-decaloxy-2-hydroxybenzophenone, 4-benzyloxy-2-hydroxybenzophenone, 2,2′,4,4′-tetrahydroxybenzophenone, and 2,2′-dihydroxy-4,4′-dimethoxybenzophenone.

Examples of the salicylic acid-based ultraviolet absorber may include phenyl salicylate, 4-t-butylphenyl-2-hydroxybenzoate, phenyl-2-hydroxybenzoate, 2,4-di-t-butylphenyl-3,5-di-t-butyl-4-hydroxybenzoate, and hexadecyl-3,5-t-butyl-4-hydroxybenzoate.

Examples of the benzotriazole-based ultraviolet absorber may include 2-(2-hydroxy-5-methylphenyl)2H-benzotriazole, 2-(3-t-butyl-2-hydroxy-5-methylphenyl)-5-chloro-2H-benzotriazole, 2-(3,5-di-t-butyl-2-hydroxyphenyl)-5-chloro-2H-benzotriazole, 2-(3,5-di-t-butyl-2-hydroxyphenyl)-2H-benzotriazole, 5-chloro-2-(3,5-di-t-butyl-2-hydroxyphenyl)-2H-benzotriazole, 2-(3,5-di-t-amyl-2-hydroxyphenyl)-2H-benzotriazole, 2-(2-hydroxy-5-t-octylphenyl)-2H-benzotriazole, 2-(2-hydroxy-4-octylphenyl)-2H-benzotriazole, 2-(2H-benzotriazol-2-yl)-4-methyl-6-(3,4,5,6-tetrahydrophtharimidylmethyl)phenol, and 2,2′-methylenebis[4-(1,1,3,3-tetramethylbutyl)-6-[(2H-benzotriazol-2-yl)phenol]].

The amount of the ultraviolet absorber is preferably 0.01 parts by weight or more, more preferably 0.02 parts by weight or more, and particularly preferably 0.04 parts by weight or more, and is preferably 1 part by weight or less, more preferably 0.5 parts by weight or less, and particularly preferably 0.3 parts by weight or less, relative to 100 parts by weight of the thermoplastic elastomer. When the using amount of the ultraviolet absorber is equal to or more than the lower limit value of the aforementioned range, light resistance can be improved. Even when the excess amount thereof exceeding the upper limit is used, further improvement is hardly achieved.

Examples of the antioxidant may include a phosphor-based antioxidant, a phenol-based antioxidant, and a sulfur-based antioxidant. A phosphor-based antioxidant is preferable because of less coloring.

Examples of the phosphor-based antioxidant may include a monophosphite-based compound such as triphenyl phosphite, diphenyl isodecyl phosphite, phenyl isodecyl phosphite, tris(nonylphenyl) phosphite, tris(dinonylphenyl) phosphite, tris(2,4-di-t-butylphenyl) phosphite, and 10-(3,5-di-t-butyl-4-hydroxybenzyl)-9,10-dihydro-9-oxa-10-phosphaphenanthrene-10-oxide; a diphosphite-based compound such as 4,4′-butylidene-bis(3-methyl-6-t-butylphenyl-di-tridecylphosphite), and 4,4′-isopropylidene-bis(phenyl-di-alkyl(C12-C15)phosphite); and compounds such as 6-[3-(3-t-butyl-4-hydroxy-5-methylphenyl)propoxy]-2,4,8,10-tetrakis-t-butyldibenzo[d,f][1.3.2]dioxaphosphepine, and 6-[3-(3,5-di-t-butyl-4-hydroxyphenyl)propoxy]-2,4,8,10-tetrakis-t-butyldibenzo[d,f][1.3.2]dioxaphosphepine.

Examples of the phenol-based antioxidant may include pentaerythrityl tetrakis[3-(3,5-di-t-butyl-4-hydroxyphenyl)propionate], 2,2-thio-diethylenebis[3-(3,5-di-t-butyl-4-hydroxyphenyl)propionate], octadecyl-3-(3,5-di-t-butyl-4-hydroxyphenyl)propionate, 3,9-bis{2-[3-(3-t-butyl-4-hydroxy-5-methylphenyl)propionyloxy]-1,1-dimethylethyl}-2,4,8,10-tetraoxaspiro[5,5]undecane, and 1,3,5-trimethyl-2,4,6-tris(3,5-di-t-butyl-4-hydroxybenzyl)benzene.

Examples of the sulfur-based antioxidant may include compounds such as dilauryl-3,3′-thiodipropionate, dimyristyl 3,3′-thiodipropionate, distearyl-3,3′-thiodipropionate, laurylstearyl-3,3′-thiodipropionate, pentaerythritol-tetrakis-(β-lauryl-thio-propionate), and 3,9-bis(2-dodecylthioethyl)-2,4,8,10-tetraoxaspiro[5,5]undecane.

The amount of the antioxidant is preferably 0.01 parts by weight or more, more preferably 0.05 parts by weight or more, and particularly preferably 0.1 parts by weight or more, and is preferably 1 part by weight or less, more preferably 0.5 parts by weight or less, and particularly preferably 0.3 parts by weight or less, relative to 100 parts by weight of the thermoplastic elastomer. When the using amount of the antioxidant is equal to or more than the lower limit value of the aforementioned range, heat stability can be improved. Even when the excess amount thereof exceeding the upper limit is used, further improvement is hardly achieved.

[3.3. Properties of Hygroscopic Resin Layer]

Since the hygroscopic resin layer contains the hygroscopic particles, it has an excellent gas barrier property. Accordingly, the moisture vapor transmission rate of the hygroscopic resin layer is usually low. Specifically, the moisture vapor transmission rate of the hygroscopic resin layer in an environment at a temperature of 40° C. and a humidity of 90% Rh, in the evaluation wherein the hygroscopic resin layer is stacked with a first composite layer having a moisture vapor transmission rate of 1.0×10⁻¹ g/m²/day to 1.5×10⁻⁴ g/m²/day, is preferably 1.0×10⁻⁴ g/m²/day or less, and more preferably 1.0×10⁻⁵ g/m²/day or less.

The hygroscopic resin layer is usually soft and has an excellent flexibility. Therefore, even when the hygroscopic resin layer is folded, cracking is not easily caused. Accordingly, the gas barrier property of the hygroscopic resin layer is unlikely to be reduced due to external force. Thus, the hygroscopic resin layer can be used as a sealing member for flexible organic EL light-emitting bodies.

Usually, the amount of outgas generation from the hygroscopic resin layer is small even when the hygroscopic resin layer is placed in a low pressure environment. In this manner, the hygroscopic resin layer has a high gas barrier property, and can favorably maintain the high gas barrier property even in a high temperature environment or in a low pressure environment. Accordingly, the hygroscopic resin layer can be suitably used in a high temperature environment and in a low pressure environment during the production process of an organic EL light-emitting body.

The hygroscopic resin layer usually has high transparency. Accordingly, the total light transmittance of the hygroscopic resin layer is usually high. Specifically, the total light transmittance of the hygroscopic resin layer is preferably 70% or more, more preferably 80% or more, and particularly preferably 90% or more. The total light transmittance may be measured in the wavelength range of 400 nm to 700 nm, using a UV-visible spectrometer.

The haze of the hygroscopic resin layer may be set depending on its use application. For example, when the hygroscopic resin layer is used as a sealing member of an organic EL light-emitting body for illumination, the haze of the hygroscopic resin layer may be high. When the hygroscopic resin layer is used as a sealing member of an organic EL light-emitting body for display devices, the haze of the hygroscopic resin layer is preferably low.

When the amount of the hygroscopic particles in the hygroscopic resin layer falls within the aforementioned range, haze of the hygroscopic resin layer can be usually kept at a low level. Specifically, the haze of the hygroscopic resin layer is preferably 3.0% or less, and more preferably 1.0% or less. The haze may be measured using a haze meter in accordance with JIS K7136.

The hygroscopic resin layer may be produced as a layer having a high refractive index. For example, the refractive index may be preferably 1.55 or more, and more preferably 1.60 or more. The refractive index may be measured using an ellipsometer (M-2000 manufactured by J. A. Woollam Japan Co., Inc.).

The adhesion to glass of the hygroscopic resin layer is preferably 5 N/25 mm or more, and more preferably 7.5 N/25 mm or more. When the adhesion to glass of the hygroscopic resin layer is equal to or more than the aforementioned value, the hygroscopic resin layer can be suitably used as a sealing member. The upper limit of the adhesion to glass of the hygroscopic resin layer is not particularly limited, and is usually 30 N/25 mm or less. The adhesion to glass of the hygroscopic resin layer may be measured in accordance with JIS K 6854-1.

[3.4. Thickness of Hygroscopic Resin Layer]

The thickness of the hygroscopic resin layer is preferably 3 μm or more, more preferably 5 μm or more, and particularly preferably 10 μm or more, and is preferably 150 μm or less, more preferably 100 μm or less, and particularly preferably 50 μm or less. When the thickness of the hygroscopic resin layer is equal to or more than the lower limit value of the aforementioned range, the thickness of the hygroscopic resin layer can be prevented from becoming non-uniform due to small foreign substances even if the hygroscopic resin layer is contaminated with such foreign substances. When the thickness thereof is equal to or less than the upper limit value of the aforementioned range, cracking in the hygroscopic resin layer can be suppressed and bending after sealing of the hygroscopic resin layer can also be suppressed. Accordingly, a uniform organic EL light-emitting body can be formed, and the organic EL light-emitting body can be thinned.

[3.5. Method for Forming Hygroscopic Resin Layer]

As the method for forming the hygroscopic resin layer, any method may be optionally adopted depending on the material of the hygroscopic resin layer.

For example, when the hygroscopic resin layer is formed of an adhesive resin, the hygroscopic resin layer may be formed by preparing an adhesive resin in a fluid form containing a solvent, applying the adhesive resin in the fluid form onto an appropriate support, and performing an operation (drying, heating, UV irradiation, and the like) for curing as necessary. In this production, the hygroscopic resin layer may usually contain components having been contained in the fluid adhesive resin. A part of the components (a curing agent, a silane coupling agent, and the like) may be modified by a reaction, or a part of the components (a solvent and the like) may be volatilized to disappear.

Alternatively, when the hygroscopic resin layer is formed of a thermoplastic elastomer resin, the hygroscopic resin layer may be formed by molding the thermoplastic elastomer resin in a film shape. The method for forming the thermoplastic elastomer resin is not particularly limited, and may be any one of a melt molding method and a solution casting method. More particularly, the melt molding methods may be categorized into an extrusion molding method, a press molding method, an inflation molding method, an injection molding method, a blow molding method, a stretch molding method, and the like. Among these methods, in order to obtain the hygroscopic resin layer having excellent mechanical strength and surface accuracy, an extrusion molding method, an inflation molding method, and a press molding method are preferable. Among these, from the viewpoint of enabling efficient and easy production of the hygroscopic resin layer, an extrusion molding method is particularly preferable. A thin hygroscopic resin layer can be formed by laminating the hygroscopic resin layer in a hot state with the first composite layer or the second composite layer immediately after the extrusion molding while nipping the hygroscopic resin layer with the first composite layer or the second composite layer.

[4. Second Composite Layer]

The second composite layer includes a second gas barrier layered body. The second composite layer preferably includes a second release layer between the hygroscopic resin layer and the second gas barrier layered body.

[4.1. Second Gas Barrier Layered Body]

The second gas barrier layered body includes a second substrate layer and a second inorganic layer disposed on at least one surface of the second substrate layer. The second inorganic layer may be disposed on only one surface of the second substrate layer, or may be disposed on both surfaces of the second substrate layer. Usually, the second inorganic layer is disposed in direct contact with the surface of the second substrate layer, and therefore the second inorganic layer and the second substrate layer are in contact with each other. However, when the surface of the second substrate layer has many convex portions which can cause cracking of the second inorganic layer, an organic layer such as an overcoat layer may be formed between the second inorganic layer and the second substrate layer. Accordingly, the second inorganic layer may be disposed indirectly on the surface of the second substrate layer via an optional layer.

(4.1.1. Second Substrate Layer)

As the second substrate layer, an optional layer selected from the range described as the first substrate layer may be used. Therefore, the material, thickness, properties, and production method of the second substrate layer may be the same as those of the first substrate layer. The second substrate layer can exert the same effects in the second gas barrier layered body as those exerted by the first substrate layer in the first gas barrier layered body.

The material and thickness of the second substrate layer are preferably the same as those of the first substrate layer from the viewpoint of suppression of curling of the composite layered body, although they may be different.

(4.1.2. Second Inorganic Layer)

As the second inorganic layer, an optional inorganic layer selected from the range described as the first inorganic layer may be used. Therefore, the material, thickness, properties, and production method of the second inorganic layer may be the same as those of the first inorganic layer. The second inorganic layer can exert the same effects in the second gas barrier layered body as those exerted by the first inorganic layer in the first gas barrier layered body.

The material and thickness of the second inorganic layer are preferably the same as those of the first inorganic layer from the viewpoint of suppression of curling of the composite layered body, although they may be different.

In the second gas barrier layered body, although the second inorganic layer may be disposed on both surfaces of the second substrate layer, the second inorganic layer is usually disposed on one surface thereof. In this case, the second inorganic layer may be disposed on the surface of the second substrate layer on the hygroscopic resin layer side (see FIG. 3), or may be disposed on the surface of the second substrate layer opposite to the hygroscopic resin layer (see FIG. 2 and FIG. 4). In particular, from the viewpoint of the suppression of curling of the composite layered body, the second inorganic layer is preferably disposed such that the first gas barrier layered body and the second gas barrier layered body are plane symmetrical to each other about the hygroscopic resin layer. Therefore, when the first inorganic layer is disposed on the surface of the first substrate layer on the hygroscopic resin layer side, the second inorganic layer is preferably disposed on the surface of the second substrate layer on the hygroscopic resin layer side. When the first inorganic layer is disposed on the surface of the first substrate layer opposite to the hygroscopic resin layer, the second inorganic layer is preferably disposed on the surface of the second substrate layer opposite to the hygroscopic resin layer.

Only one second inorganic layer may be disposed on one surface of the second substrate layer. Alternatively, two or more second inorganic layers may be disposed thereon.

(4.1.3. Optional Layer)

The second gas barrier layered body may further include an optional layer in combination with the second substrate layer and the second inorganic layer. For example, when two or more second inorganic layers are disposed on one surface of the second substrate layer, the second gas barrier layered body may include an organic layer between the two or more second inorganic layers.

[4.2. Second Release Layer]

As the second release layer, an optional layer selected from the range described as the first release layer may be used. Therefore, the material, thickness, and production method of the second release layer may be the same as those of the first release layer. The second release layer can exert the same effects in the second composite layer as those exerted by the first release layer in the first composite layer.

[4.3. Moisture Vapor Transmission Rate of Second Composite Layer]

The moisture vapor transmission rate of the second composite layer in an environment at a temperature of 40° C. and a humidity of 90% Rh is preferably 5.0×10⁻² g/m²/day or less, more preferably 5.0×10⁻³ g/m²/day or less, and particularly preferably 5.0×10⁻⁴ g/m²/day or less. When the second composite layer has such an excellent gas barrier property as expressed by the aforementioned moisture vapor transmission rate, a decrease in hygroscopic function of the hygroscopic particles contained in the hygroscopic resin layer can be effectively suppressed. The lower limit of the moisture vapor transmission rate is desirably 0 g/m²/day. However, even when the moisture vapor transmission rate thereof is equal to or more than this value, the second composite layer may be suitably used as long as the moisture vapor transmission rate thereof is equal to or less than the aforementioned upper limit.

[5. Optional Layer]

The composite layered body may further include an optional constituent in combination with the aforementioned first composite layer, hygroscopic resin layer, and second composite layer.

For example, an anti-blocking layer, an antistatic layer, a hard coat layer, an electroconductivity imparting layer, an antifouling layer, and a concavo-convex structural layer may be provided to one surface of the composite layered body. The electroconductivity imparting layer may have been patterned by printing or etching. Such an optional layer may be formed, for example, by a method of applying a material of an optional layer onto a surface and curing the layer; and a method of bonding an optional layer to the surface.

[6. Thickness of Composite Layered Body]

The thickness of the composite layered body is preferably 25 μm or more, more preferably 40 μm or more, and particularly preferably 50 μm or more, and is preferably 250 μm or less, more preferably 150 μm or less, and particularly preferably 100 μm or less. When the thickness of the composite layered body is equal to or more than the lower limit value of the aforementioned range, the gas barrier property can be enhanced. When the thickness thereof is equal to or less than the upper limit value of the aforementioned range, the film can be thinned.

[7. Method for Producing Composite Layered Body]

The composite layered body may be produced by any production method which allows for obtaining a desired composite layered body. For example, the composite layered body including the first composite layer, the hygroscopic resin layer, and the second composite layer in this order may be produced by preparing a first composite layer and a second composite layer, and bonding the first composite layer and the second composite layer via a hygroscopic resin layer. When the first composite layer and the second composite layer are prepared as a long-length film layer, the composite layered body can be produced by a roll-to-roll process with high production efficiency.

For example, when the hygroscopic resin layer is formed from an adhesive resin containing the hygroscopic particles, the composite layered body may be produced by a production method including:

(i) a step of applying an adhesive resin in a fluid state onto a surface of a first composite layer or a second composite layer, and curing the adhesive resin as necessary, to form a hygroscopic resin layer; and

(ii) a step of bonding the first composite layer and the second composite layer via the hygroscopic resin layer to obtain a composite layered body.

As another example, when the hygroscopic resin layer is formed from a thermoplastic elastomer resin containing the hygroscopic particles, the gas barrier layered body may be produced by a production method including:

(iii) a step of molding a thermoplastic elastomer resin in a film shape to obtain a hygroscopic resin layer; and

(iv) a step of stacking a first composite layer, the hygroscopic resin layer, and a second composite layer in this order, and bonding the stacked layers through thermos-compression bonding to obtain a composite layered body.

[8. Method for Storing Hygroscopic Resin Layer]

The use of the aforementioned composite layered body enables storing of the hygroscopic resin layer provided to the composite layered body while a decrease in hygroscopic function of the hygroscopic particles contained in the hygroscopic resin layer is suppressed.

The storing of the composite layered body is usually effected in a state of being wound up in a roll shape. In this storing, the composite layered body may be wound up such that the first composite layer faces outward or such that the first composite layer faces inward. In the state of being wound up in a roll shape, the hygroscopic resin layer is protected by the first composite layer. When the composite layered body includes the second composite layer, the hygroscopic resin layer is protected also by the second composite layer. Since the first composite layer and the second composite layer block the moisture entering the hygroscopic resin layer, intrusion of moisture into the hygroscopic resin layer is suppressed during a storage period. Since this can reduce moisture to reach the hygroscopic particles contained in the hygroscopic resin layer, the moisture adsorption of the hygroscopic particles can be suppressed. As a result, a decrease in hygroscopic function of the hygroscopic particles can be suppressed.

The storing of the composite layered body is usually effected in a state of being sealed. For the sealing, an optional member which can seal the composite layered body may be used. Examples thereof may include a sealing container and sealing bag. As a specific example, as a moisture-proof bag formed of a sheet having an aluminum layer is commercially available, such a moisture-proof bag may be suitably used. The moisture vapor transmission rate of the member capable of sealing the composite layered body is preferably 0.0003 g/m²/day to 0.1 g/m²/day. When the composite layered body is stored in such a sealed state, a decrease in hygroscopic function of the hygroscopic particles contained in the hygroscopic resin layer can be particularly effectively suppressed.

[9. Usage of Hygroscopic Resin Layer]

The hygroscopic resin layer stored as described above may be used as a sealing member for organic EL light-emitting bodies. Usually, such a sealing is achieved by peeling the first composite layer and the second composite layer and bonding the hygroscopic resin layer as a single film member to the organic EL light-emitting body. Since the hygroscopic particles can adsorb the moisture entering the organic EL light-emitting body, the sealing with the hygroscopic resin layer enables suppression of the performance deterioration of the organic EL light-emitting body due to moisture. Furthermore, since the hygroscopic resin layer is used for sealing as a single film member which eliminates the need for a support film layer, a device including the organic EL light-emitting body (a light-emitting device, an image display device, and the like) can be thinned.

The hygroscopic resin layer is usually used in combination with a sealing substrate. As the sealing substrate, a multi-layer film including a substrate layer and an inorganic layer disposed on the substrate layer may be used. For example, favorable sealing of an organic EL light-emitting body can be achieved by bonding the organic EL light-emitting body, the hygroscopic resin layer, and the sealing substrate in this order.

The intrusion of moisture into the organic EL light-emitting body may be further suppressed by further forming, in addition to the sealing substrate, the hygroscopic resin layer on the outer surface of a substrate on which the light-emitting layer of the organic EL light-emitting body has been formed.

### EXAMPLES

Hereinafter, the present invention will be specifically described by illustrating Examples. However, the present invention is not limited to the Examples described blow. The present invention may be optionally modified for implementation without departing from the scope of claims of the present invention and its equivalents. In the following description, “%” and “part” representing quantity are on the basis of weight, unless otherwise specified. The operation described in the following was performed under the conditions of normal temperature and normal pressure, unless otherwise specified. In the following description “PET” represents polyethylene terephthalate, unless otherwise specified.

[Evaluation Method]

[Method for Measuring Moisture Vapor Transmission Rate]

The moisture vapor transmission rate was measured by creating pressure by water vapor equivalent to that at 40° C. and 90% Rh on both sides of a sample, using a differential pressure measuring device (“DELTAPERM” manufactured by Technolox Ltd.) having a circular measurement region with a diameter of 8 cm.

[Method for Evaluating Hygroscopic Function of Hygroscopic Particles Contained in Hygroscopic Resin Layer]

The composite layered body produced in each of Examples and Comparative Examples was stored in a normal humidity environment for about 1 week. Herein, the normal humidity environment refers to an environment at a temperature of 20° C. to 25° C. and a humidity of 50% Rh to 60% Rh. After that, the first composite layer and the second composite layer were peeled off to take out the hygroscopic resin layer. The hygroscopic resin layer thus taken was left to stand in an environment of 23° C. and 55% for 60 minutes, and measured for weight changes. A larger weight increase is indicative of higher hygroscopic function of the hygroscopic particles contained in the hygroscopic resin layer.

### Example 1

A release PET film (“HY-US20” manufactured by Higashiyama Film Co., Ltd.) which includes a PET film as the first substrate layer and a first release layer disposed on one surface of this PET film was prepared. A surface of the release PET film, on which the first release layer was not disposed, was coated with aluminum by sputtering using a sputter device to form a first inorganic layer with a thickness of 400 nm. Accordingly, a first composite layer was obtained which includes: a first gas barrier layered body containing the first substrate layer and the first inorganic layer; and the first release layer formed on one surface (the surface on the first substrate layer side) of the first gas barrier layered body.

The moisture vapor transmission rate of this first composite layer was measured. As a result, the moisture vapor transmission rate was about 3×10⁻³ g/m²/day to 4×10⁻³ g/m²/day.

A second composite layer including a second release layer having a release force different from that of the first release layer was also produced by the following procedure.

A release PET film (“HY-S10” manufactured by Higashiyama Film Co., Ltd.) including a PET film as a second substrate layer and a second release layer disposed on one surface of this PET film was prepared. A surface of the release PET film, on which the second release layer was not disposed, was coated with aluminum by sputtering using a sputter device to form a second inorganic layer with a thickness of 400 nm. Accordingly, a second composite layer was obtained which includes: a second gas barrier layered body containing the second substrate layer and the second inorganic layer; and the second release layer formed on one surface (the surface on the second substrate layer side) of the second gas barrier layered body.

The moisture vapor transmission rate of this second composite layer was measured. As a result, the moisture vapor transmission rate was about 3×10⁻³ g/m²/day to 4×10⁻³ g/m²/day.

100 parts of an adhesive agent (“OC3447” manufactured by Saiden Chemical Industry Co., Ltd.) containing an acryl-based adhesive polymer, 14 parts of methyl ethyl ketone as a solvent, 10 parts of a plasticizer (“PN6120” manufactured by ADEKA Corporation), and 10 parts of zeolite particles (average dispersed particle diameter: 20 nm, weight change ratio when they are left to stand at 20° C. and 90% Rh for 24 hours: 3% or more) as hygroscopic particles were mixed. Accordingly, an adhesive resin in a liquid state was obtained. This adhesive resin was applied onto the first release layer of the first composite layer such that the dried thickness became 20 μm, and dried in an oven at 80° C. to form a hygroscopic resin layer.

Immediately thereafter, the hygroscopic resin layer and the second release layer of the second composite layer were bonded to each other. Accordingly, a composite layered body having a layer structure of first inorganic layer/first substrate layer/first release layer/hygroscopic resin layer/second release layer/second substrate layer/second inorganic layer was obtained.

This composite layered body was measured for the weight change of the hygroscopic resin layer when it was left to stand for 60 minutes after stored for 1 week, by the aforementioned method. As a result, the weight change of the hygroscopic resin layer was an increase of 0.18%.

### Comparative Example 1

A composite layered body having a layer structure of first substrate layer/first release layer/hygroscopic resin layer/second release layer/second substrate layer was produced in the same manner as that in Example 1, except that the first inorganic layer was not disposed on the first substrate layer, and the second inorganic layer was not disposed on the second substrate layer.

This composite layered body was measured for the weight change of the hygroscopic resin layer when it was left to stand for 60 minutes after stored for 1 week, by the aforementioned method. As a result, almost no weight change of the hygroscopic resin layer was observed.

### Example 2

As the substrate layer, a film (“ZEONOR Film ZF14” manufactured by ZEON Corporation, thickness: 50 μm) made of an alicyclic polyolefin resin was prepared. As a coating liquid for forming a release layer, a silicone resin coating liquid which contains 20 parts of a curable silicone resin (“KS-847(H)” manufactured by Shin-Etsu Chemical Co., Ltd.) and 0.3 parts of a catalyst (“PL-50T” manufactured by Shin-Etsu Chemical Co., Ltd.) was prepared. The coating liquid was applied onto one surface of the substrate layer, and thereafter heated in an oven at 120° C. for performing a drying treatment and a curing treatment. Thus, a release layer was formed. The amount of this release layer per unit area was 0.1 g/m².

After that, a surface of the substrate layer, on which the release layer was not formed, was coated with aluminum by sputtering using a sputter device to form an inorganic layer with a thickness of 400 nm. Accordingly, a composite layer as the first composite layer and the second composite layer was obtained, which includes: a gas barrier layered body containing the substrate layer and the inorganic layer; and the release layer formed on one surface (the surface on the substrate layer side) of the gas barrier layered body.

The moisture vapor transmission rate of this composite layer was measured. As a result, the moisture vapor transmission rate was about 3×10⁻³ g/m²/day to 4×10⁻³ g/m²/day.

A thermoplastic resin pellet containing a thermoplastic elastomer having a styrene-isoprene copolymer skeleton was prepared. The thermoplastic elastomer was a hydrogenated product of a styrene-isoprene block copolymer having an alkoxysilyl group. In this hydrogenated product, not only non-aromatic carbon-carbon unsaturated bonds but also aromatic carbon-carbon unsaturated bonds of the styrene-isoprene block copolymer had been hydrogenated. In this thermoplastic elastomer, a ratio wA/wB of a weight fraction wA of a polymer block [A] containing an aromatic vinyl compound unit to a weight fraction wB of a polymer block [B] containing a chain conjugated diene compound unit was 50/50. To this resin pellet, zeolite particles (average dispersed particle diameter: 20 nm, weight change ratio when they are left to stand at 20° C. and 90% Rh for 24 hours: 3% or more) as hygroscopic particles were mixed to produce a thermoplastic elastomer resin. At this time, the amount of the zeolite particles was adjusted such that the concentration of the zeolite particles in the thermoplastic elastomer resin became 5% by weight. Then, simultaneously with producing the thermoplastic elastomer resin as previously described, this thermoplastic elastomer resin was molded by an extrusion molding method to obtain a hygroscopic resin layer with a thickness of 20 μm.

Immediately thereafter, the hygroscopic resin layer was bonded to the aforementioned two composite layers in such a manner to be inserted therebetween. Thus, a composite layered body having a layer structure of inorganic layer/substrate layer/release layer/hygroscopic resin layer/release layer/substrate layer/inorganic layer was obtained.

This composite layered body was measured for the weight change of the hygroscopic resin layer when it was left to stand for 60 minutes after stored for 1 week, by the aforementioned method. As a result, the weight change of the hygroscopic resin layer was an increase of 0.2%.

### Comparative Example 2

A composite layered body having a layer structure of substrate layer/release layer/hygroscopic resin layer/release layer/substrate layer was produced in the same manner as that in Example 2, except that the inorganic layer was not disposed on the substrate layer.

This composite layered body was measured for the weight change of the hygroscopic resin layer when it was left to stand for 60 minutes after stored for 1 week, by the aforementioned method. As a result, almost no weight change of the hygroscopic resin layer was observed.

### Example 3

A composite layered body having a layer structure of first inorganic layer/first substrate layer/first release layer/hygroscopic resin layer/second release layer/second substrate layer/second inorganic layer was obtained in the same manner as that in Example 1, except that 10 parts of magnesium oxide particles (average dispersed particle diameter: 45 nm, weight change ratio when they are left to stand at 20° C. and 90% Rh for 24 hours: 20%) were used as the hygroscopic particles in place of the zeolite particles.

This composite layered body was measured for the weight change of the hygroscopic resin layer when it was left to stand for 60 minutes after stored for 1 week, by the aforementioned method. As a result, the weight change of the hygroscopic resin layer was an increase of 0.2%.

[Results]

The results of the aforementioned Examples and Comparative Examples are summarized in the following Table 1.

TABLE 1
[Results of Examples and Comparative Examples]

| | Ex. 1 | Comp. Ex. 1 | Ex. 2 | Comp. Ex. 2 | Ex. 3 |
|---|---|---|---|---|---|
| Inorganic layer | Al | — | Al | — | Al |
| Substrate | PET | PET | COP | COP | PET |
| layer | | | | | |
| Hygroscopic | Adhesive | Adhesive | Thermoplastic | Thermoplastic | Adhesive |
| resin | resin | resin | elastomer | elastomer | resin |
| layer | | | resin | resin | |
| Hygroscopic | Zeolite | Zeolite | Zeolite | Zeolite | MgO |
| particles | | | | | |
| Weight | +0.18% | 0 | +0.20% | 0 | +0.20% |
| change | | | | | |

### DISCUSSION

As understood from Table 1, the hygroscopic particles contained in the hygroscopic resin layer of the composite layered body according to each of Comparative Examples lost its hygroscopic function after the composite layered body was stored for 1 week. In contrast to this, the hygroscopic particles contained in the hygroscopic resin layer of the composite layered body according to each of Examples successfully exert high hygroscopic function even after the composite layered body was stored for 1 week. From these results, it was confirmed that according to the composite layered body of the present invention, the hygroscopic resin layer can be stored while a decrease in hygroscopic function of the hygroscopic particles is suppressed.

In particular, an excellent result was achieved in Example 2. The thermoplastic elastomer itself used in Example 2 has a small amount of moisture adsorption because of its molecular structure. Also, in a resin containing a thermoplastic elastomer like in Example 2, a solvent such as methyl ethyl ketone, which is likely to contain moisture, is unlikely to remain. The present inventor considers that this enabled particularly effective suppression of a decrease in hygroscopic function of the hygroscopic particles in Example 2.

### REFERENCE SIGN LIST

10, 20, 30 and 40 composite layered body
100 hygroscopic resin layer
110 hygroscopic particles
200 first composite layer
210 first release layer
220 first gas barrier layered body
221 first substrate layer
222 first inorganic layer
300 peelable film layer
400 second composite layer
410 second release layer
420 second gas barrier layered body
421 second substrate layer
422 second inorganic layer

1. A composite layered body comprising: a resin layer and a first composite layer, the resin layer containing particles of which a weight change ratio when they are left to stand at 20° C. and 90% Rh for 24 hours is 3% or more, wherein
the first composite layer includes a first release layer and a first gas barrier layered body in this order from a side of the resin layer side, and
the first gas barrier layered body includes a first substrate layer and a first inorganic layer disposed on at least one surface of the first substrate layer.

2. The composite layered body according to claim 1, wherein the first substrate layer contains an alicyclic polyolefin resin.

3. The composite layered body according to claim 1, wherein the particles contain one or more substances selected from the group consisting of zeolite, magnesium oxide, and calcium oxide.

4. The composite layered body according to claim 1, wherein a moisture vapor transmission rate of the first composite layer is 5.0×10⁻² g/m²/day or less at 40° C. and 90% Rh.

5. The composite layered body according to claim 1, wherein the resin layer contains an adhesive resin or a thermoplastic elastomer resin.

6. The composite layered body according to claim 1, wherein the first inorganic layer is a layer of a material containing a metallic element.

7. The composite layered body according to claim 1, wherein the first inorganic layer is a layer of a material containing an aluminum element.

8. The composite layered body according to claim 1, comprising the first composite layer, the resin layer, and a second composite layer in this order, wherein
the second composite layer includes a second gas barrier layered body, the second gas barrier layered body including a second substrate layer and a second inorganic layer disposed on at least one surface of the second substrate layer.

9. The composite layered body according to claim 8, wherein the second composite layer include a second release layer between the resin layer and the second gas barrier layered body.

10. A method for storing a resin layer, comprising sealing and storing the composite layered body according to claim 1 in a state of being wound up in a roll shape.
